(19) United States
(12) Patent Application Publication
(10) Pub. No.: US 2025/0113736 A1
(43) Pub. Date: Apr. 3, 2025

(54) DEVICES, SYSTEMS, AND METHODS INCLUDING MICRO- OR NANO- CANTILEVER STRUCTURES

(71) Applicants: The MITRE Corporation, McLean, VA (US); Massachusetts Institute of Technology, Cambridge, MA (US)

(72) Inventors: Henry WEN, Reading, MA (US); Andrew Greenspon, McLean, VA (US); Matthew Saha, Bedford, MA (US); Dirk Englund, Brookline, MA (US)

(73) Assignees: The MITRE Corporation, McLean, VA (US); Massachusetts Institute of Technology, Cambridge, MA (US)

(21) Appl. No.: 18/899,787

(22) Filed: Sep. 27, 2024

Related U.S. Application Data
(60) Provisional application No. 63/541,644, filed on Sep. 29, 2023.
(60) Provisional application No. 63/657,660, filed on Jun. 7, 2024.

(51) Int. Cl. H10N 30/20; G02F 1/295; H01L 25/16

(52) U.S. Cl. CPC H10N 30/2042; G02F 1/295; H01L 25/167

(57) ABSTRACT

A cantilever may include a first dielectric layer that has a first intrinsic stress and a second dielectric layer overlying the first dielectric layer that has a second intrinsic stress that is different than the first intrinsic stress. The difference between the first and second intrinsic stresses may cause the cantilever to curve. A second dielectric layer can comprise a plurality of crossbars oriented at an angle relative to a length of the cantilever to reduce curvature in a width direction of the cantilever. The second dielectric layer can be patterned with a waveguide. The cantilever may be piezoelectrically actuated.

### CROSS-REFERENCE TO RELATED APPLICATIONS

This application claims the benefit of U.S. Provisional Application No. 63/541,644, filed Sep. 29, 2023, and 63/657,660, filed Jun. 7, 2024, the entire contents of each of which is incorporated herein by reference.

### FIELD

The present disclosure relates generally to micro-mechanical and nano-mechanical cantilevers for use in microelectromechanical systems (MEMS), photonic devices, micro-robotic devices, and the like.

### BACKGROUND

The scalability of a micron-scale or nano-scale system is often restricted by an inability to effectively interconnect system components without compromising important system characteristics (e.g., size or efficiency). For example, the scalability of a photonic integrated circuit may be limited by an inability to perform crucial functions such as the steerable projection and collection of optical modes between the circuit and a set of targets in free space without using devices that have relatively large footprints (e.g., MEMs mirrors) or devices that are challenging to integrate (e.g., optical phase arrays). These challenges can hamper the development of technologies that can be formed from networks of micron-scale and nano-scale devices.

### SUMMARY

Described are micron-scale and nano-scale curving or curling cantilever structures for use in a wide range of applications, including as components of photonic and electronic integrated circuits. The provided cantilevers can be fabricated using wafer-scale fabrication techniques and materials (e.g., CMOS fabrication techniques and materials) and can comprise a stack of dielectric layers having differing intrinsic stress values. When a cantilever is released from its underlying substrate during fabrication, the non-zero stress gradient across its constituent dielectric layers causes the cantilever to deflect and curve along its length.

The topmost dielectric layer (relative to the substrate to which the cantilever is anchored) of a cantilever can be geometrically configured to amplify the cantilever's deflection along its length. Etching the topmost dielectric layer into a plurality of lateral crossbars, for example, can redirect lateral stress (e.g., stress along the width of the cantilever) in the cantilever along the cantilever's length to increase the longitudinal deflection of the cantilever. Varying properties of the crossbar pattern such as the crossbar duty cycle can program the curvature of the cantilever and, in some embodiments, can enable to cantilever to assume complex geometric structures once released from the underlying substrate.

The curving of a cantilever can be passive or can be actively controlled. A passive curving cantilever may permanently assume a curved shape after being released from the underlying substrate. Actively controlled curving cantilevers, on the other hand, can be moved as needed between two or more curvature states, e.g., via piezoelectric actuation. For example, an active curving cantilever may be configured to be moved between an undeflected state and a deflected state.

The provided cantilevers can be implemented as optical interconnects in optical systems such as photonic integrated circuits (PICs) by patterning a waveguide channel within the topmost cantilever layer and can enable crucial functionalities such as the steerable projection and collection of multiple optical modes between a PIC and a set of targets in free space. Active curving cantilevers (e.g., piezoelectrically actuated cantilevers) in particular can enable, e.g., two-dimensional beam scanning from anywhere on a photonic chip over a large number of diffraction limited spots in the far field. Advantageously, unlike beam scanning approaches that rely on reflective scanners, integrated optical phase arrays, or scanning fibers, the disclosed cantilevers are highly scalable and have small footprints (e.g., less than 1 mm²), wide fields-of-view, and broadband outputs. As a result, the provided cantilevers can facilitate the creation of complex optical systems such as quantum computers.

Example applications of the cantilevers to several technical fields are also described. In particular, applications of the cantilevers to photonic circuits such as qubit control systems are provided.

In some embodiments, a cantilever includes a first dielectric layer that has a first intrinsic stress and a second dielectric layer overlying the first dielectric layer that has a second intrinsic stress that is different than the first intrinsic stress. The cantilever can be curved along a longitudinal dimension of the cantilever due to a difference between the first and second intrinsic stresses. The second dielectric layer can include a plurality of crossbars oriented at an angle relative to a length of the cantilever to control curvature in a lateral dimension of the cantilever.

A patterning of the plurality of crossbars can be periodic. In some embodiments, a period of the patterning of the plurality of crossbars is greater than or equal to 0.5 microns. In some embodiments, each crossbar of the plurality of crossbars has a length greater than or equal to 0.25 microns and less than or equal to 5 microns. A length of each crossbar of the plurality of crossbars can be greater than a period of the patterning of the plurality of crossbars. In some embodiments, a ratio of the length of each crossbar of the plurality of crossbars to the period of the patterning of the plurality of crossbars is at least 0.5. In some embodiments, a ratio of the length of each crossbar of the plurality of crossbars to the period of the patterning of the plurality of crossbars changes along the longitudinal dimension of the cantilever. Each crossbar of the plurality of crossbars may protrude from a surface of the second dielectric layer. A height of each crossbar of the plurality of crossbars relative to the surface of the second dielectric layer may be greater than 0 microns and less than or equal to 2 microns. The angle at which the plurality of crossbars is patterned may be approximately 90° or less than 90°.

The cantilever can be fabricated with a removable sacrificial layer that binds the cantilever to a substrate. When the sacrificial layer is removed, the cantilever can deflect along the longitudinal dimension of the cantilever relative to the substrate. In some embodiments, the cantilever deflects in a direction away from the substrate. In some embodiments, the cantilever deflects in a direction toward the substrate. In some embodiments, the deflection of the cantilever relative to the substrate increases from the first end along the longitudinal dimension of the cantilever. A maximum deflection of the cantilever along the longitudinal dimension of the cantilever can be at least 1 mm.

A chemical composition of the first dielectric layer may be the same as a chemical composition of the second dielectric layer. The second dielectric layer can include an oxide.

The cantilever can include one or more waveguides. The one or more waveguides can be patterned in the second dielectric layer along the length of the cantilever. The cantilever can be a component of a photonic integrated circuit.

In some embodiments, the cantilever includes a piezoelectric layer disposed between the first dielectric layer and the second dielectric layer. The piezoelectric layer may have a third intrinsic stress that is greater than the first intrinsic stress of the first dielectric layer. When a voltage is applied across the piezoelectric layer, the cantilever may deflect along its length relative to the substrate. The direction of the deflection of the cantilever relative to the substrate may depend on the sign of the voltage applied to the piezoelectric layer and an amount by which the cantilever deflects relative to the substrate may depend on the magnitude of the voltage applied to the piezoelectric layer.

In some embodiments, the cantilever is a component of a clamping device. In some embodiments, the cantilever curls along its length to form a helix. In some embodiments, the longitudinal dimension of the cantilever in a first portion of the cantilever is oriented in a first direction and the longitudinal dimension of the cantilever in a second portion of the cantilever is oriented in a second direction. The second direction can be orthogonal to the first direction. In some embodiments, the cantilever includes a ball lens disposed at one end of the cantilever. In some embodiments, the cantilever comprises one or more layers disposed between the first dielectric layer and the second dielectric layer.

A photonic system provided herein can comprise a photonic integrated circuit (PIC) chip comprising a cantilever. The cantilever can include a first dielectric layer that has a first intrinsic stress, a second dielectric layer overlying the first dielectric layer that has a second intrinsic stress that is different than the first intrinsic stress, and a waveguide patterned in the second dielectric layer. The cantilever can be curved along a longitudinal dimension of the cantilever due to a difference between the first and second intrinsic stresses. The second dielectric layer can include a plurality of crossbars oriented at an angle relative to the length of the cantilever to control curvature in a lateral dimension of the cantilever.

The cantilever can be fabricated with a removable sacrificial layer that binds the cantilever to a substrate of the PIC chip. When the sacrificial layer is removed, the cantilever can deflect in a direction along the longitudinal dimension of the cantilever relative to the substrate.

The waveguide can be patterned along the longitudinal dimension of the cantilever. The photonic system can include an optoelectronic component that is not a component of the PIC chip, wherein the waveguide is configured to optically couple to the optoelectronic component when the cantilever deflects relative to the substrate.

In some embodiments, a provided system includes a substrate, a first cantilever anchored to the substrate at one end, wherein the first cantilever forms an arch along its length over the substrate, and a second cantilever anchored to the first cantilever at one end and comprising: a first dielectric layer, wherein the first dielectric layer has a first intrinsic stress, and a second dielectric layer overlying the first dielectric layer, wherein the second dielectric layer has a second intrinsic stress that is different than the first intrinsic stress. The second cantilever may be curved along a longitudinal dimension of the second cantilever due to a difference between the first and second intrinsic stresses. The second dielectric layer can include a plurality of crossbars oriented at an angle relative to the longitudinal dimension of the second cantilever to control curvature in a lateral dimension of the cantilever.

In some embodiments, a cantilever includes a first dielectric layer, wherein the first dielectric layer has a first intrinsic stress, and a second dielectric layer overlying the first dielectric layer, wherein the second dielectric layer has a second intrinsic stress that is different than the first intrinsic stress, wherein a difference between the first and second intrinsic stresses causes the cantilever to curve.

In some embodiments, a cantilever comprises a first dielectric layer, wherein the first dielectric layer has a first intrinsic stress; a second dielectric layer overlying the first dielectric layer, wherein the second dielectric layer has a second intrinsic stress that is different than the first intrinsic stress, a first piezoelectric layer disposed between the first dielectric layer and the second dielectric layer in a first longitudinal half of the cantilever and a second piezoelectric layer disposed between the first dielectric layer and the second dielectric layer in a second longitudinal half of the cantilever. A system can include this cantilever along with one or more voltage sources configured to apply a first voltage to the first piezoelectric layer and a second voltage to the second piezoelectric layer.

In some embodiments, a cantilever comprises a first dielectric layer, wherein the first dielectric layer has a first intrinsic stress, a second dielectric layer overlying the first dielectric layer, wherein the second dielectric layer has a second intrinsic stress that is different than the first intrinsic stress, a first piezoelectric layer disposed between the first dielectric layer and the second dielectric layer in a first lateral portion of the cantilever, and a second piezoelectric layer disposed between the first dielectric layer and the second dielectric layer in a second lateral portion of the cantilever. A system can include this cantilever along with one or more voltage sources configured to apply a first voltage to the first piezoelectric layer and a second voltage to the second piezoelectric layer.

### BRIEF DESCRIPTION OF THE FIGURES

The patent or application file contains at least one drawing executed in color. Copies of this patent or patent application publication with color drawings will be provided by the office upon request and payment of the necessary fee.

The invention will now be described, by way of example only, with reference to the accompanying drawings.

FIG. 1 shows a head-on, cross-sectional view of a cantilever, according to some embodiments.

FIG. 2A shows a top-down view of a cantilever, according to some embodiments.

FIG. 2B shows a perspective view of a cantilever, according to some embodiments.

FIG. 3A shows lateral deformation in a cantilever without a patterning, according to some embodiments.

FIG. 3B shows lateral deformation in a cantilever with crossbar patterning, according to some embodiments.

FIG. 4A shows a side view of a cantilever prior to release, according to some embodiments.

FIG. 4B shows a side view of a cantilever immediately following release, according to some embodiments.

FIG. 4C shows a side view of a deflected cantilever, according to some embodiments.

FIG. 5A provides example data showing relationships between cantilever deflection, crossbar period, and crossbar width.

FIG. 5B provides example data characterizing the deflected state of a cantilever configured to have a constant radius of curvature.

FIG. 6A shows a head-on, cross-sectional view of a cantilever patterned with a waveguide, according to some embodiments.

FIG. 6B shows a perspective view of a a cantilever patterned with a waveguide, according to some embodiments.

FIG. 7 shows a side view of a deflected, waveguide-patterned cantilever, according to some embodiments.

FIG. 8 shows a head-on, cross-sectional view of a piezoelectrically-actuated cantilever, according to some embodiments.

FIG. 9A shows a side view of a piezoelectrically-actuated cantilever with no voltage applied across the piezoelectric layer, according to some embodiments.

FIG. 9B shows a side view of a piezoelectrically-actuated cantilever with a voltage applied across the piezoelectric layer, according to some embodiments.

FIG. 10 shows a head-on, cross-sectional view of a piezoelectrically-actuated cantilever that is patterned with a waveguide, according to some embodiments.

FIG. 11 shows an example of a crossbar pattern for creating helical structures.

FIG. 12 shows an example of a ball-shaped structure.

FIG. 13 shows an example of a toroidal structure.

FIG. 14A shows a gripping actuator for a micro-robotic system, according to some embodiments.

FIG. 14B shows a gripping actuator for a micro-robotic system, according to some embodiments.

FIG. 14C shows a gripping actuator for a micro-robotic system, according to some embodiments.

FIG. 15 shows a sideways-twisting cantilever, according to some embodiments.

FIG. 16A shows a “candy-cane” photonic coupler, according to some embodiments.

FIG. 16B shows a “candy-cane” photonic coupler directing waveguide output toward a reflective substrate, according to some embodiments.

FIG. 17A shows a “stair-step” photonic coupler, according to some embodiments.

FIG. 17B shows waveguide output from a “stair-step” photonic coupler, according to some embodiments.

FIG. 18 shows an angle-boosted cantilever, according to some embodiments.

FIGS. 19A-B show twisted, piezoelectrically-controlled cantilevers, according to some embodiments.

FIG. 20 show ball-lens terminated cantilevers, according to some embodiments.

FIG. 21 shows a periodic optical switch that is implement using a piezoelectrically-actuated cantilever patterned with a waveguide, according to some embodiments.

FIG. 22 shows a photonic cantilever with low output divergence, according to some embodiments.

FIG. 23A shows a system for high-speed optical pulsing for qubit control, according to some embodiments.

FIG. 23B shows a system for high-speed optical pulsing for qubit control, according to some embodiments.

FIG. 24 shows a system for controlling qubit color centers relative to photonic integrated circuit (PIC) edge excitation and collection or top-down confocal excitation and collection, according to some embodiments.

FIG. 25A shows a cantilever with two independent directionally controlled segments, according to some embodiments.

FIG. 25B shows a cantilever with two independent directionally controlled segments, according to some embodiments.

### DETAILED DESCRIPTION

Described are micron-scale and nano-scale curving or curling cantilever structures and devices and systems including such structures for use in a wide range of applications. For example, described are cantilever structures that can be used as components of photonic and electronic integrated circuits. The provided cantilevers can be fabricated using wafer-scale fabrication techniques and materials (e.g., conventional CMOS fabrication techniques and materials). An exemplary cantilever can comprise a stack of dielectric layers having differing intrinsic stress values. When the cantilever is released from its underlying substrate during fabrication, the non-zero stress gradient across its constituent dielectric layers causes the cantilever to deflect and curve along its length.

The topmost dielectric layer (relative to the substrate to which the cantilever is anchored) of a cantilever can be geometrically configured to amplify the cantilever's deflection along its length. Etching the topmost dielectric layer into a plurality of lateral crossbars, for example, can redirect lateral stress (e.g., stress along the width of the cantilever) in the cantilever along the cantilever's length to increase the longitudinal deflection of the cantilever. Varying properties of the crossbar pattern such as the crossbar duty cycle can program the curvature of the cantilever and, in some embodiments, can enable to cantilever to assume complex geometric structures once released from the underlying substrate.

The curving of a cantilever can be passive or can be actively controlled. A passive curving cantilever may permanently assume a curved shape after being released from the underlying substrate. Actively controlled curving cantilevers, on the other hand, can be moved as needed between two or more curvature states, e.g., via piezoelectric actuation. For example, an active curving cantilever may be configured to be moved between an undeflected state and a deflected state.

The provided cantilevers can be implemented as optical interconnects in optical systems such as photonic integrated circuits (PICs) by patterning a waveguide channel within the topmost cantilever layer and can enable crucial functionalities such as the steerable projection and collection of multiple optical modes between a PIC and a set of targets in free space. Active curving cantilevers (e.g., piezoelectrically actuated cantilevers) in particular can enable, e.g., two-dimensional beam scanning from anywhere on a photonic chip over a large number of diffraction limited spots in the far field. Advantageously, unlike beam scanning approaches that rely on reflective scanners, integrated optical phase arrays, or scanning fibers, the disclosed cantilevers are highly scalable and have small footprints (e.g., less than 1 mm²), wide fields-of-view, and broadband outputs. As a result, the provided cantilevers can facilitate the creation of complex optical systems such as quantum computers.

According to various embodiments, cantilevers configured according to the principles described herein are used in micro- and nano-electromechanical systems (MEMs and NEMs), micro- and nano-scale robotics, and self-assembling micro- and nano-scale structures.

Any of the systems, methods, techniques, and/or features disclosed herein may be combined, in whole or in part, with any other disclosed systems, methods, techniques, and/or features. As used herein, the singular forms “a”, “an”, and “the” include the plural reference unless the context clearly dictates otherwise. Reference to “about” a value or parameter or “approximately” a value or parameter herein includes (and describes) variations that are directed to that value or parameter per se. For example, description referring to “about X” includes description of “X”. It is understood that aspects and variations of the invention described herein include “consisting of” and/or “consisting essentially of” aspects and variations. When a range of values or values is provided, it is to be understood that each intervening value between the upper and lower limit of that range, and any other stated or intervening value in that stated range, is encompassed within the scope of the present disclosure. Where the stated range includes upper or lower limits, ranges excluding either of those included limits are also included in the present disclosure.

### Passive Curving Cantilevers

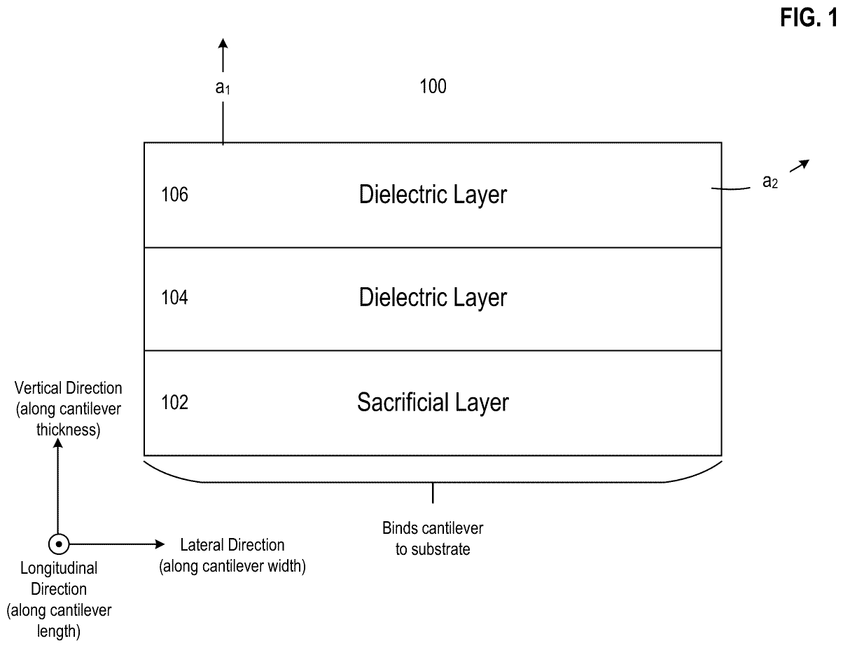

A head-on, cross-sectional view of an exemplary cantilever 100 is provided in FIG. 1. Cantilever 100 may be beam-shaped, i.e., may be longer in a first dimension (the longitudinal direction in FIG. 1) than in a second dimension (the lateral direction in FIG. 1) or a third dimension (the vertical direction in FIG. 1). Reference herein to the length of cantilever 100 (e.g., description of cantilever 100 deflecting or deforming “along its length”) may be interpreted as reference to the longest, longitudinal dimension of cantilever 100, while reference to the width of cantilever 100 (e.g., description of cantilever 100 deflecting or deforming “along its width”) may be interpreted as reference to the shorter, lateral dimension of cantilever 100 that is co-planar with the longitudinal dimension of cantilever 100.

As shown, cantilever 100 may include several layers: a sacrificial (i.e., release) layer 102, a first, bottom dielectric layer 104, and a second, top dielectric layer 106. Sacrificial layer 102 may bind cantilever 100 to a substrate (e.g., a substrate of an integrated circuit chip) and may be any material layer deposited in the layer stack of cantilever 100 that can be preferentially removed or etched away, e.g., by a wet chemical etch or a gaseous chemical etch, compared to the other materials that constitute cantilever 100 in order to release the overlying layers of cantilever 100 (layers 104-106) from the substrate. For example, sacrificial layer 102 may be a layer of amorphous silicon that can be etched away using a xenon difluoride gas that does not etch the overlying cantilever layers (layers 104-106). An amorphous silicon sacrificial layer can also be removed using various concentrations of potassium hydroxide. If the overlying dielectric layers 104 and 106 do not comprise silicon dioxide, then sacrificial layer 102 can be silicon dioxide or another oxide glass and may be removed using a wet etch of hydrofluoric acid.

Dielectric layers 104 and 106 may be any thin film dielectrics having intrinsic stresses (e.g., silicon dioxide or silicon nitride). The intrinsic stress of layer 106 may be different (e.g., more compressive or more tensile) than the intrinsic stress of layer 104; this difference may be the result of material or chemical differences between layer 104 and layer 106 or, if layer 104 and layer 106 have the same chemical composition, the result of differences in the conditions under which each layer was deposited during the fabrication of cantilever 100. For example, if both layer 104 and layer 106 comprise silicon dioxide or silicon nitride, layer 104 may be configured to have a different intrinsic stress than layer 106 by depositing layer 104 at a different flow rate than the flow rate used to deposit layer 106. Other deposition conditions that may be varied in order to configure the stresses of layers 104 and 106 include the mixture of precursor gases used during deposition, plasma pressure, plasma frequency, and power in a chemical vapor deposition chamber. Post-deposition annealing can also change the intrinsic stress of an as-deposited film.

When sacrificial layer 102 is removed and cantilever 100 is released from the substrate, the gradient of intrinsic stress between layer 104 and layer 106 may cause cantilever 100 to deflect along its length (e.g., longitudinally deflect) relative to the substrate (e.g., as indicated by arrow a₁). In order to concentrate the deflection caused by the gradient of intrinsic stress between layer 104 and layer 106 in the longitudinal direction and to reduce lateral strain in cantilever 100 that can cause cantilever 100 to curl along its width (as indicated by arrow a₂), layer 106 can be geometrically patterned atop layer 104 such that lateral strain is redirected in the longitudinal direction—i.e., along the length of cantilever 100—to increase the amount by which cantilever 100 deflects along its length.

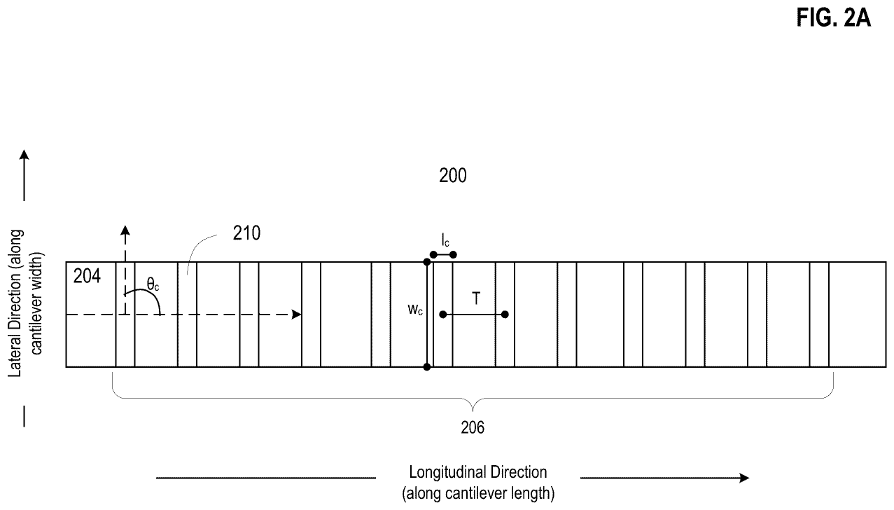

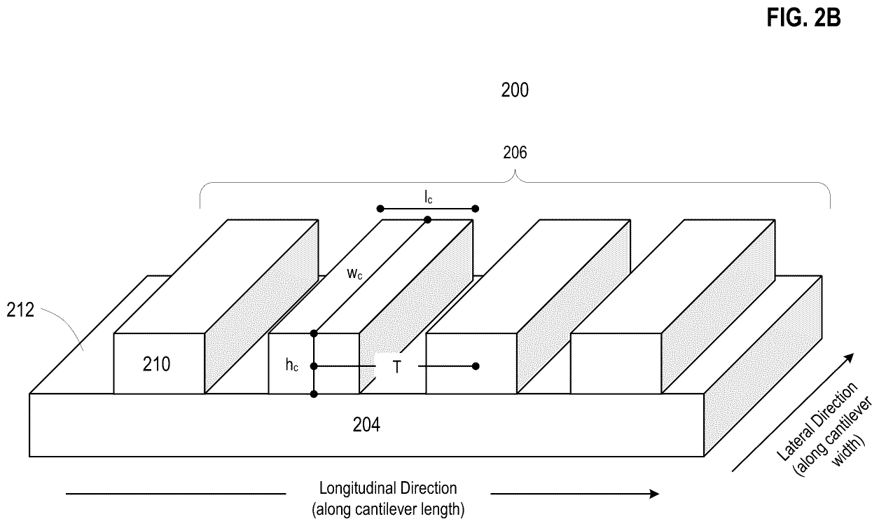

A top-down view and a perspective view of an exemplary cantilever 200 comprising a second dielectric layer 206 that is geometrically patterned atop a first dielectric layer 204 are provided in FIG. 2A and FIG. 2B, respectively. As shown, second dielectric layer 206 may comprise a patterning of crossbars 210 deposited on a surface 212 of first dielectric layer 204. Each crossbar 210 may have a length l_{c}, a width w_{c}, and a height h_{c} relative to surface 212 and may be oriented at an angle θ_{c} relative to the length of cantilever 100.

Dielectric layer 206 may be formed from a dielectric material such as an oxide (e.g., silicon dioxide, aluminum oxide, hafnium dioxide etc.), silicon nitride, or silicon oxy-nitride. During the fabrication of cantilever 100, this dielectric material may be deposited on top of the underlying cantilever layers (e.g., on top of first dielectric layer 204 and the underlying sacrificial layer) and subsequently etched to form crossbars 210. Intrinsic stress may be added to second dielectric layer 206 by varying the density of the dielectric material, by varying the conditions under which second dielectric layer 206 is deposited, and by adding dopants.

Relative to its width w_{c}, the length l_{c} of a given crossbar 210 may be small. For example, the length l_{c} of a given crossbar 210 may be 90%, 80%, 70%, 60%, 50%, 40%, 30%, 20%, or 10% smaller the width w_{c} of the crossbar. In some embodiments, the length l_{c} of a given crossbar 210 is approximately (e.g., is within 1%, 10%, 15%, or 20% of) 0.5, 0.75, 1, 1.25, 1.5, 1.75, 2, 2.25, 2.5, 2.75, or 3 microns In some embodiments, the length l_{c} of a given crossbar 210 is greater than or equal to 0.1, 0.15, 0.2, 0.25, 0.3, 0.35, 0.4, 0.45, or 0.5 μm. In some embodiments, the length l_{c} of a given crossbar 210 is less than or equal to 5, 4.5, 4, 3.5, 3, 2.5, 2, 1.5, or 1 μm. Each crossbar 210 may have the same length l_{c}, or the lengths of crossbars 210 may vary, e.g., may vary along the length of cantilever 100 or along the width of cantilever 100. In some embodiments, the length l_{c} of a crossbar 210 may taper along the width or the height of the crossbar.

A crossbar 210 may be as wide as the underlying layers (e.g., first dielectric layer 204) of cantilever 200 or may be more or less wide than the underlying layers of (e.g., first dielectric layer 204) of cantilever 100. In some embodiments, the width w of a given crossbar 210 is greater than or equal to 1, 5, 10, 15, 25, 50, 75, 100, 200, 300, 400, or 500 μm. In some embodiments, the width w_{c} of a given crossbar 210 is less than or equal to 1000, 900, 800, 700, 600, 500, or 400 μm. The width w_{c} of each crossbar 210 may affect the amount by which layer 206 can suppress and redirect the lateral strain in cantilever 200 in the longitudinal direction. In some embodiments, each crossbar 210 has the same width w_{c}; in other embodiments, the widths of crossbars 210 vary, e.g., along the length of cantilever 200 or along the width of cantilever 200. In some embodiments, the width w_{c} of a crossbar 210 may taper along the length or the height of the crossbar.

Crossbars 210 may or may not protrude from surface 212. If a given crossbar 210 does not protrude from surface 212, its height h_{c} relative to surface 212 may be negligible. If a given crossbar 210 does protrude from surface 212, its height h_{c} relative to surface 212 may be greater than 0 μm and less than or equal to 0.05, 0.1, 0.15, 0.2, 0.25, 0.3, 0.35, 0.4, 0.45, 0.5, 0.55, 0.6, 0.65, 0.7, 0.75, 0.8, 0.85, 0.9, 0.95, 1, 1.05, 1.1, 1.15, 1.2, 1.25, 1.3, 1.35, 1.4, 1.45, 1.5, 1.55, 1.6, 1.65, 1.7, 1.75, 1.8, 1.85, 1.9, 1.95 or 2 μm. Each crossbar 210 can have the same height h_{c}, or the heights of crossbars 210 may vary, e.g., along the length of cantilever 200 or along the width of cantilever 200. In some embodiments, the height h_{c} of a crossbar 210 may taper along the length or the width of the crossbar.

The angle θ_{c} at which a given crossbar 210 is oriented relative to the length of cantilever 200 may be an angle between a line parallel to the length of cantilever 200 and a line parallel to the width of the crossbar. In some embodiments, a crossbar 210 is patterned such that its width is orthogonal to the length of cantilever 100—i.e., the angle θ_{c} at which the crossbar is oriented relative to the length of cantilever 200 may be approximately 90°. A crossbar 210 can also be patterned such that its width is oriented diagonally with respect to the length of cantilever 100—e.g., the angle θ_{c} at which the crossbar is oriented relative to the length of cantilever 200 may be less than 90° or greater than 90°. In some cases, each crossbar 210 may be oriented at the same angle θ_{c} relative to the length of cantilever 200. In others, the orientations of crossbars 210 may vary, e.g., along the length of cantilever 200 or along the width of cantilever 200. The angle(s) at which crossbars 210 are oriented relative to the length of cantilever 200 may affect the direction in which cantilever 200 deflects when released from the substrate.

The patterning of the plurality of crossbars 210 may be periodic along the length of cantilever 200. That is, the patterning of crossbars 210 may repeat after a given distance T along the length of cantilever 200, where T is the period of the crossbar patterning. If each crossbar 210 has the same geometry and the same orientation relative to the length of cantilever 200, the period T of the crossbar patterning may be the longitudinal separation distance between analogous points on adjacent crossbars, as illustrated in FIG. 2B. In such cases, the period T may be directly related to the longitudinal density of crossbars 210. On the other hand, if the geometries or the orientations of crossbars 210 varies along the length of cantilever 200, the period T of the crossbar patterning may be the longitudinal separation distance between analogous points in repeating crossbar pattern segments. For example, if dielectric layer 206 is divided into repeating segments having the following crossbar pattern:
a first crossbar oriented at a first angle θ_{c1};
a second crossbar oriented at a second angle θ_{c2};
a third crossbar oriented at a third angle θ_{c3},
   then the period T of the crossbar patterning may be the longitudinal separation distance between analogous points on the first crossbar in a first segment and the first crossbar in a second segment that is adjacent to the first segment.

In some embodiments, the period T of the crossbar patterning is greater than or equal to 0.05, 0.1, 0.5, 1, 1.5, 2, 2.5, 3, 3.5, 4, 4.5, 5, 5.5, 6, 6.5, 7, or 7.5 μm. In some embodiments, the period T of the crossbar patterning is less than or equal to 15, 14.5, 14, 13.5, 13, 12.5, 12, 11.5, 11, 10.5, 10, 9.5, 9, 8.5, 8, or 7.5 μm. In some embodiments, the period T is approximately equal to (e.g., with 1%, 5%, 10%, or 15% of) half of the longitudinal length of cantilever 200. In some embodiments, the period T is at least 20, at least 30, at least 40, at least 50, at least 60, at least 70, at least 80, at least 90, or at least 100 μm. The period T of the crossbar patterning can remain constant along the length of cantilever 200 or can vary (e.g., increase or decrease) along the length of cantilever 200.

If each crossbar 210 has the same length l_{c}, the duty cycle of the crossbar patterning, defined as the ratio of the crossbar length l_{c} to the period T of the crossbar patterning (Duty Cycle=l_{c}/T) may range between 0 and 1. For example, the crossbar patterning can have a duty cycle in the range 0-0.25, 0-0.5, 0-0.75, or 0-0.99. If second dielectric layer 206 has a crossbar patterning with a low duty cycle (e.g., a duty cycle less than 0.25), second dielectric layer 206 may be capable of redirecting a greater amount of lateral strain in cantilever 100 along the length of cantilever 100; as such, a cantilever having low duty cycle crossbar patterning may, when released from its substrate, deflect along its lengths by a greater amount than a cantilever having a higher duty cycle crossbar patterning.

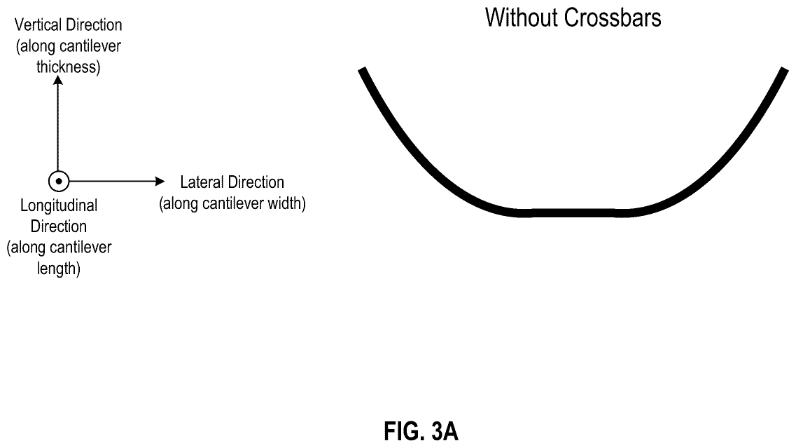

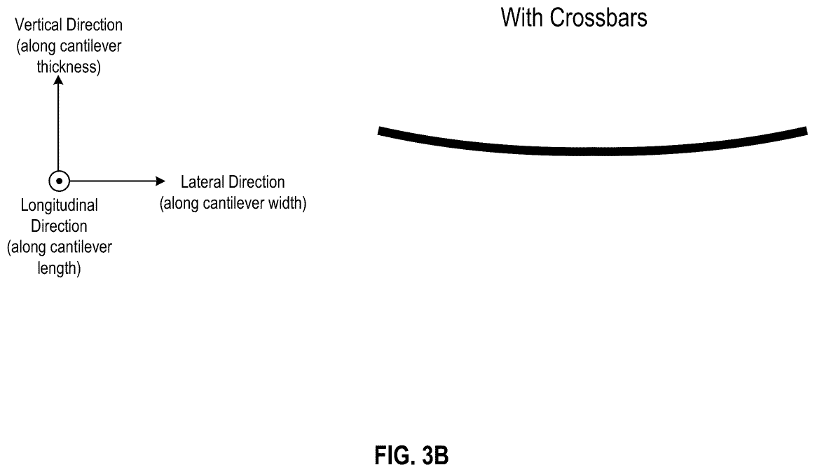

As previously noted, the crossbar patterning of the topmost dielectric layer may, when the cantilever is released from its substrate, redirect lateral strain in the cantilever in a longitudinal direction in order to increase the amount by which the cantilever deflects in the longitudinal direction. FIGS. 3A-3B illustrate qualitative differences in the lateral curvature of a released cantilever that does not have crossbars (FIG. 3A) and the lateral curvature of a released cantilever that does have crossbars (FIG. 3B). As shown, the lateral curvature in a released cantilever with crossbars (FIG. 3B) is suppressed relative to the lateral curvature in a released cantilever without crossbars (FIG. 3A).

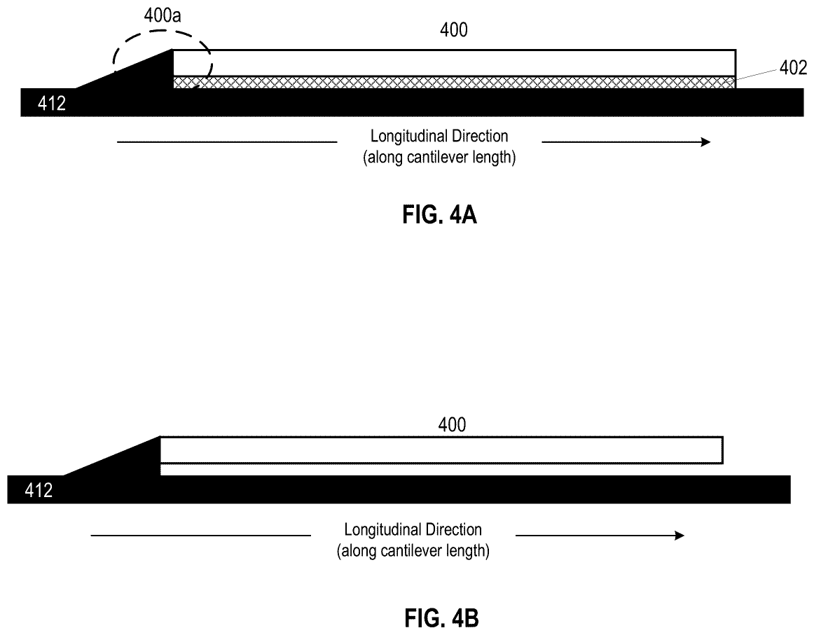

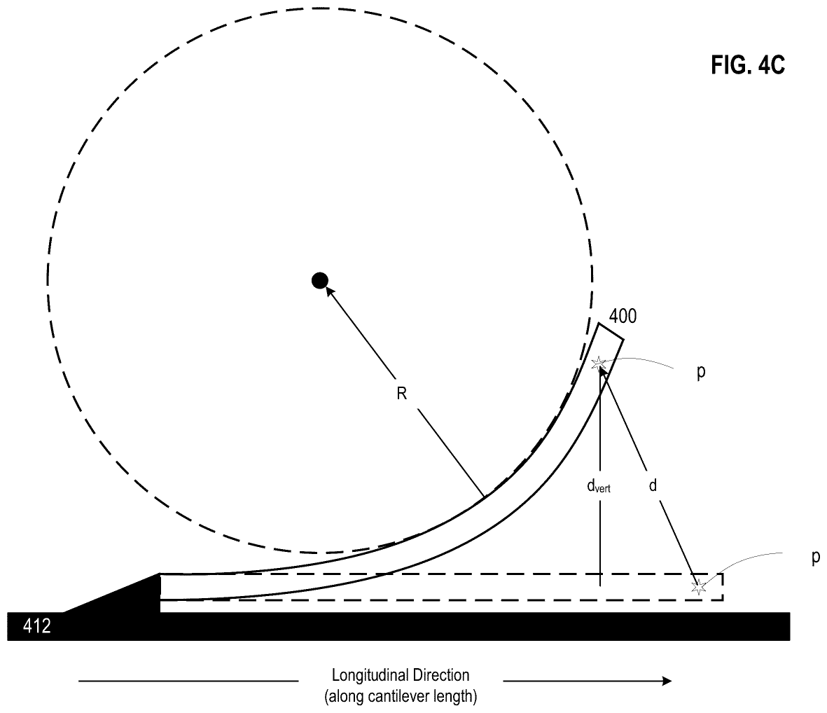

FIGS. 4A-4C depict side views of an exemplary cantilever 400 prior to the removal of its sacrificial layer 402 (FIG. 4A), immediately following the removal of sacrificial layer 402 (FIG. 4B), and after its deflection (FIG. 4C). During the fabrication of cantilever 400, sacrificial layer 402 may be deposited between a substrate 412 and an overlying layer of cantilever 400 (e.g., a first dielectric layer such as layer 104 shown in FIG. 1) to bind cantilever 400 along its length to substrate 412, as illustrated in FIG. 4A. Substrate 412 may be any CMOS-compatible material suitable for wafer-scale fabrication techniques (e.g., silicon). A portion of cantilever 400 (e.g., one end 400a, as shown in FIGS. 4A-4C, or, if more complex curling behavior is desired, another portion along the length of cantilever 400) may be anchored to substrate 412. When sacrificial layer 402 is removed, the length of cantilever 400 may extend from the anchored portion (e.g., end 400a) in a direction parallel to the surface of substrate 412 (FIG. 4B). Cantilever 400 may then deflect relative to substrate 412 due to the differences in the intrinsic stresses of its dielectric layers (e.g., layers 104-106 shown in FIG. 1, layers 204-206 shown in FIGS. 2A-2B), as shown in FIG. 4C. The deflection may be amplified due to a redirection of lateral strain along the longitudinal direction by the geometric patterning of the topmost dielectric layer (e.g., dielectric layer 206 shown in FIGS. 2A-2B) of cantilever 400.

In some embodiments, the geometric patterning of the topmost dielectric layer causes cantilever 400 to deflect along its length in a direction away from the substrate (as illustrated in FIG. 4C). In other embodiments, the geometric patterning of the topmost dielectric layer causes cantilever 400 to deflect along its length in a direction toward the substrate (e.g., causes cantilever 400 to form an semi-circular or semi-ellipsoid arch relative to the substrate). In other embodiments, the geometric patterning of the topmost dielectric layer causes cantilever 400 to twist one or more times along its length to form a (partial) helix. In other embodiments, the geometric patterning of the topmost dielectric layer causes cantilever 400 to twist along its length and to deflect along its length.

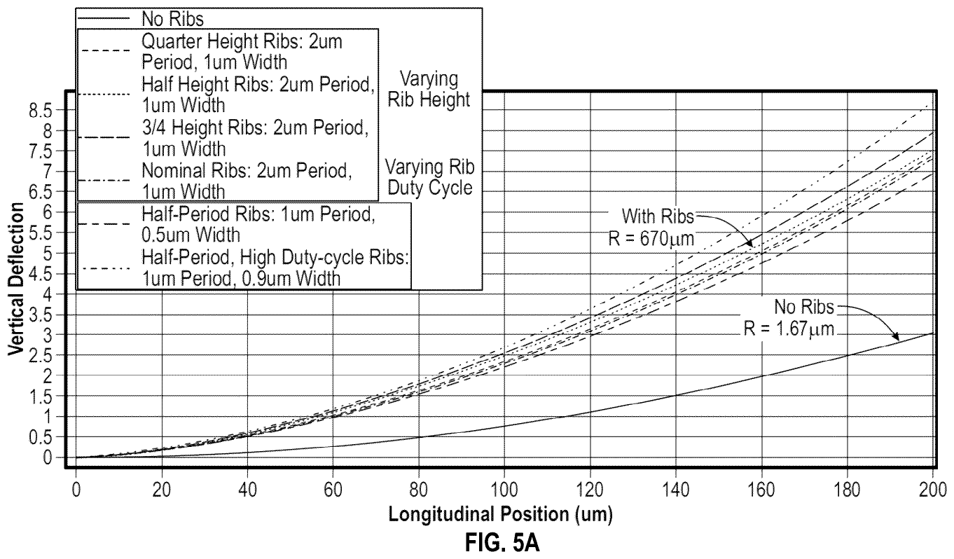

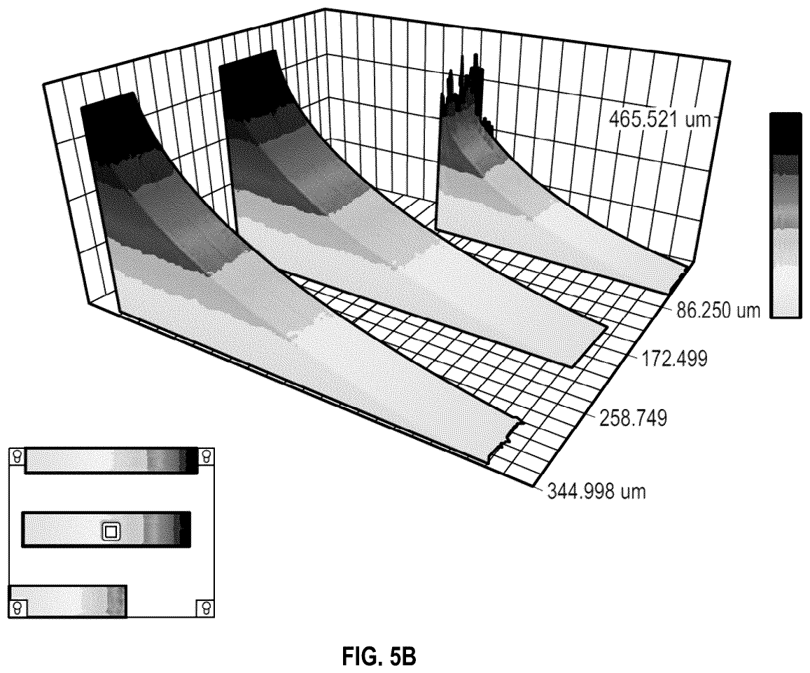

The amount by which cantilever 400 deflects at a given point p along its length when released may be the magnitude of a vector d between a location of point p in the deflected state and a location of point p in the undeflected state (indicated by dashed lines in FIG. 4C). The vertical deflection of cantilever 400 at point p may be given by the vertical component dᵥₑᵣₜ of vector d. In some embodiments, a maximum value of dᵥₑᵣₜ along the length of cantilever 100 may be greater than or equal to 100 microns, 200 microns, 300 microns, 400 microns, 500 microns, 600 microns, 700 microns, 800 microns, 900 microns, or 1000 microns. Example data showing a relationship between crossbar height, crossbar duty cycle, and vertical deflection in a cantilever comprising crossbars oriented at a 90° angle relative to the cantilever length is provided in FIG. 5A. (Note that the term “rib” in FIG. 5A is interchangeable with the term “crossbar” as used herein.)

Various embodiments of the cantilevers disclosed herein may achieve a large vertical deflection over a short longitudinal distance. As illustrated in FIG. 4C, when deflected, cantilever 400 may comprise one or more curved portions. The radius of curvature R of cantilever 400 may be constant or may change along the length of cantilever 400. In some embodiments, a curved portion of cantilever 400 has a radius of curvature R that is greater than or equal to 500, 600, 700, 800, 900, or 1000 μm. In some embodiments, a curved portion of cantilever 100 has a radius of curvature R that is less than or equal to 500, 400, 300, 200, 100, 50, 25, or 10 μm. Example data characterizing the deflected state of a cantilever configured to have a constant radius of curvature is provided in FIG. 5B.

A cantilever can be “programmed” during fabrication to assume a variety of three-dimensional configurations following its release from the underlying substrate by controlling the patterning of the topmost dielectric layer. A cantilever may therefore to be used to form self-assembling curved or helical micro-structures. For example, a cantilever may be used to perform micron-scale origami or kirigami.

### Curving Cantilevers for Photonic Applications

The provided cantilevers can have integrated photonic components and can be configured to be implemented in a photonic system such as a photonic integrated circuit (PIC) chip. For example, a cantilever may include one or more waveguide channels that can receive and transmit optical signals from other photonic devices (e.g., from a laser, from another waveguide, etc.). During fabrication, such a cantilever may be bonded to a substrate of a photonic system (e.g., a substrate of a PIC chip) by its sacrificial layer. The deflection of the cantilever once released may facilitate optical signal transmission and/or receipt via the waveguide channel(s) in the cantilever in two or more dimensions. For example, the cantilever may be used to transmit optical signals from the PIC chip to an off-chip photonic device situated above the PIC chip.

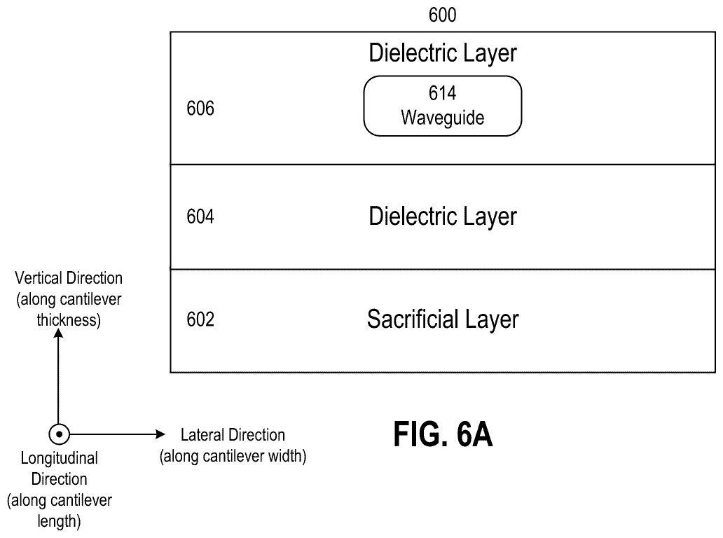

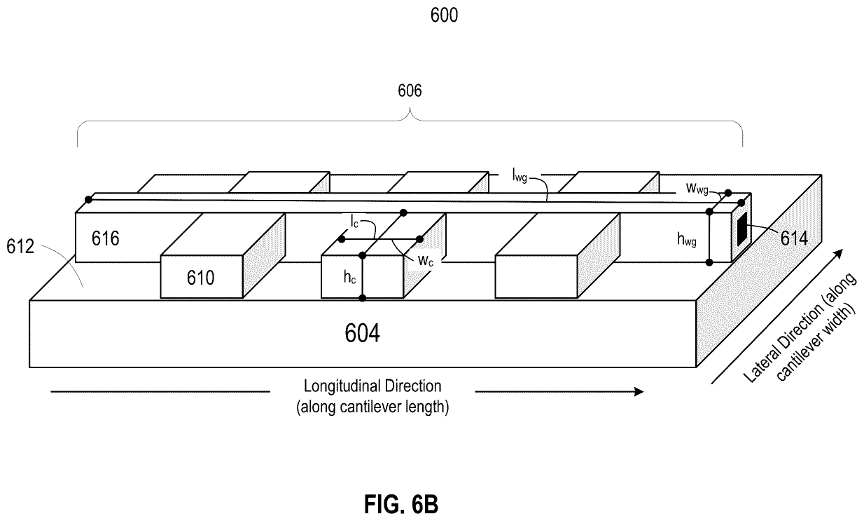

As shown in FIGS. 6A-6B, a waveguide 614 can be oriented along the length of a cantilever 600 and can form a channel within a second, topmost dielectric layer 606 of cantilever 600. Waveguide 614 may be formed using a dielectric material with low optical loss (e.g., optical loss of less than 1 dB/cm). Waveguide 614 may be oriented parallel to the length of the cantilever (e.g., oriented along the longitudinal direction) and can be positioned proximally or distally to the center of cantilever 600.

Dielectric layers 604 and 606 (like, e.g., dielectric layers 104 and 106 shown in FIG. 1) may have different intrinsic stresses. During fabrication, cantilever 600 may be anchored to the substrate of a photonic system (e.g., the substrate of a PIC chip) by a sacrificial layer 602. When sacrificial layer 602 is removed, the difference between the intrinsic stress of dielectric layer 604 and the intrinsic stress of dielectric layer 606 may cause cantilever 600 to deflect along its length (e.g., in the longitudinal direction), thereby curving waveguide 614.

Layer 606 can be geometrically patterned such that, when sacrificial layer 602 is removed, the longitudinal deflection of cantilever 600 (and, therefore, of waveguide 614) is amplified and lateral deflection of cantilever 600 is suppressed. For example, layer 606 can comprise a plurality of crossbars 610 (FIG. 6B). A dielectric cladding material 616 that matches the material used to form crossbars 610 may coat waveguide 614. Cladding 616 may have a length l_{wg}, a width w_{wg}, and a height (relative to a surface 212 of second dielectric layer 106) h_{wg}. The total height of waveguide 614 and cladding 616 may be similar to the heights of the surrounding crossbars 610. The amount of cladding 616 coating waveguide 614 may be a minimum amount necessary to protect waveguide 614 from damage. In some embodiments, the amount of cladding 616 on either side of waveguide 614 is less than or approximately equal to 0.25, 0.5, 0.75, or 1 μm.

Crossbars 610 may be patterned on one side of waveguide 614 or on both sides of waveguide 614. If crossbars 610 are patterned on both sides of waveguide 614, the crossbar patterning on one side of waveguide 614 may differ from crossbar patterning on the other side of waveguide 614. When released, cantilever 600 may form shapes of varying complexities.

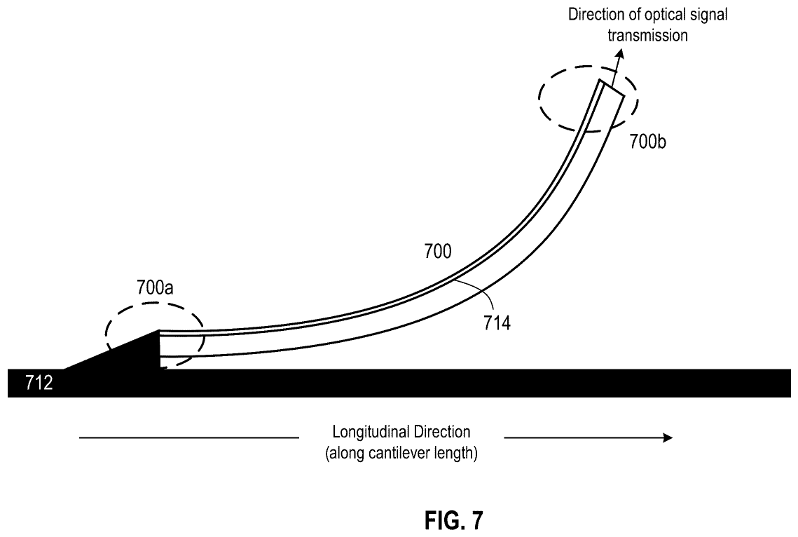

FIG. 7 provides a side view of a released cantilever 700 that is patterned with a waveguide 714. The substrate 712 to which end 700a of cantilever 700 is anchored may host one or more optical components (e.g., one or more components of a PIC chip). At the anchored end 700a of cantilever 700, waveguide 714 may be optically coupled to one of these optical components. Alternatively, waveguide 714 may extend past the anchored end 700a onto substrate 712. At the unanchored end 700b of cantilever 700, waveguide 714 may be optically coupled to an optoelectronic component that is not hosted on substrate 712 (e.g., an off-chip component, such as a component of a separate PIC). Optical signals can be received by waveguide 714 (or, more specifically, by the portion of waveguide 714 contained in cantilever 700) at either end 700a or 700b and may propagate along the length of cantilever 700. The optical path followed by optical signals propagating through waveguide 714 may depend on the shape that cantilever 700 obtains upon release from substrate 700.

A cantilever with integrated photonic components such as cantilever 600 or cantilever 700 can be fabricated on the same PIC as other active broadband integrated photonic components. For example, a cantilever with integrated photonic components can be fabricated on a PIC with Mach-Zehnder interferometers (MZIs), couplers, and ring resonators. Accordingly, light that is coupled into a waveguide in the cantilever (e.g., waveguide 614) or transmitted out of the waveguide can be controlled (e.g., modulated) without being transmitted off-chip.

### Active Curving Cantilevers

The provided cantilevers can be configured such that their deflection is actively controllable. That is, rather than being configured to deflect and remain deflected following its release from its substrate, a cantilever may be configured to deflect on-demand. Control of the deflection of a cantilever may be binary (e.g., a cantilever may be switchable between an undeflected state and a single deflected state), discrete (e.g., a cantilever may be switchable between an undeflected state and two or more distinct deflected states), or continuous (e.g., a cantilever may be adjustable between a continuum of configurations between an undeflected state and a fully deflected state).

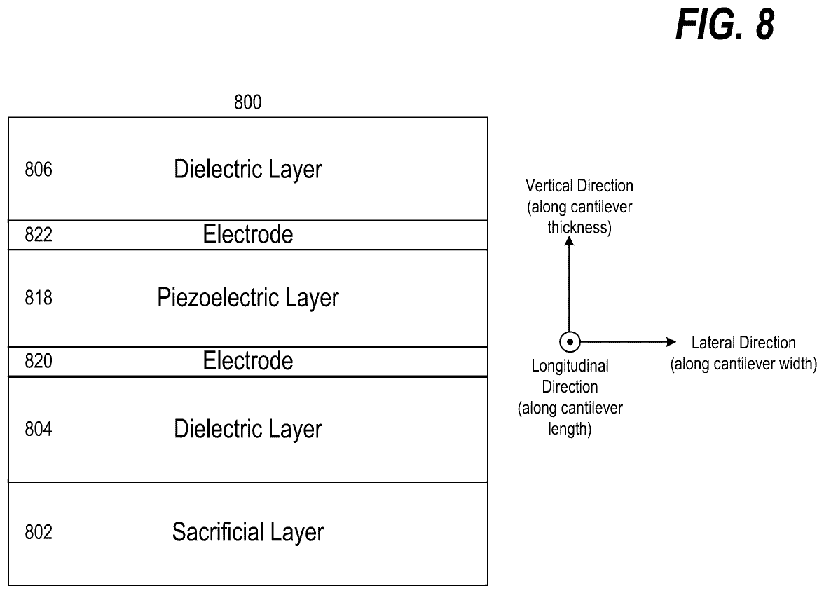

A cross-sectional view of exemplary actively controllable cantilever 800 is shown in FIG. 8. In this embodiment, cantilever 800 comprises a pair of dielectric layers 804 and 806 having differing intrinsic stresses as well as a layer 818 of piezoelectric material overlying a first dielectric layer 804. Sandwiching piezoelectric layer 818 may be a pair of conductive electrodes 820-822. A second dielectric layer 806 may overlay electrode 822. Electrodes 820-822 may be electrically connected (e.g., by wires or conductive traces in the substrate to which cantilever 800 is anchored) to a voltage source (e.g., a battery, an AC/DC power supply, etc.). Applying a voltage across piezoelectric layer 818 using the voltage source may cause piezoelectric layer 818 to mechanically deform. If the voltage is applied to piezoelectric layer 818 when sacrificial layer 802 is removed and cantilever 800 is released, the mechanical deformation of piezoelectric layer 818 may cause cantilever 800 to deflect along its length.

Piezoelectric layer 818 may be formed from a piezoelectric material having an intrinsic tensile stress. More generally, the piezoelectric material that constitutes piezoelectric layer 818 may have an intrinsic stress that is more positive than the intrinsic stress of the underlying dielectric layer 804. Suitable piezoelectric materials include (but are not limited to) aluminum nitride, aluminum scandium nitride, and barium titanate.

Electrodes 820-822 may have negligible intrinsic stress and may be deposited on piezoelectric layer 818 in layers that are as thin as possible while still allowing necessary conduction of electric current and generation of voltage. In some embodiments, each electrode is less than 300, less than 250, less than 200, or less than 150 nm thick. Suitable electrode materials include (but are not limited to) aluminum and copper.

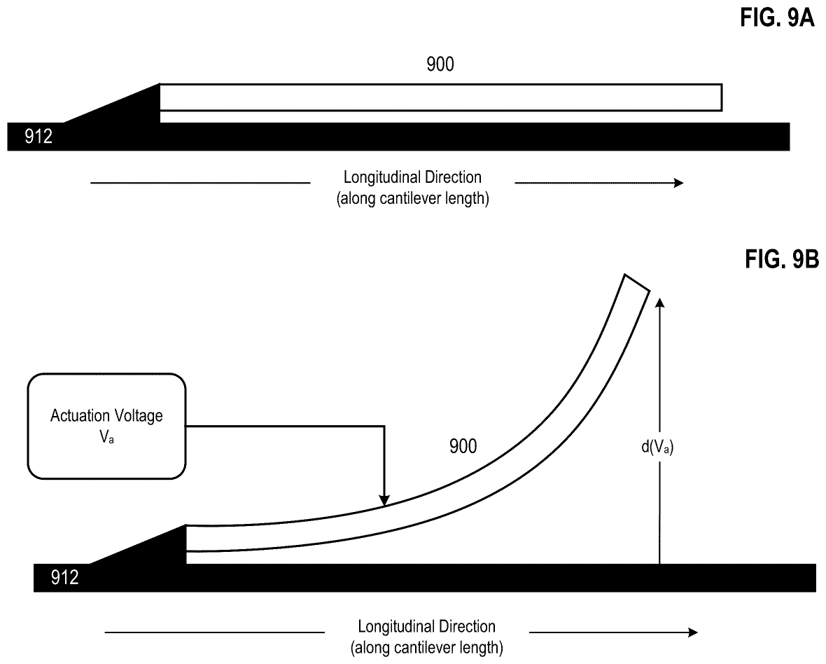

FIGS. 9A-9B depict side views of a piezoelectrically actuated cantilever 900. Cantilever 900 may comprise a piezoelectric layer structure (not shown) similar or identical to that of cantilever 800 shown in FIG. 8. When cantilever 900 is released from its substrate 912 but no voltage is applied across the piezoelectric layer, cantilever 900 may be in an undeflected state wherein the length of cantilever 900 is parallel to substrate 912 (FIG. 9A). However, when an actuation voltage Va is applied across the piezoelectric layer, the mechanical deformation of the piezoelectric material may cause cantilever 900 to deflect along its length relative to substrate 912 (FIG. 9B). Cantilever 900 may remain in a deflected state until the actuation voltage is turned off and the piezoelectric layer returns to its unactuated state, at which point cantilever 900 may revert to its undeflected configuration.

The amount by which cantilever 900 deflects, along with the direction in which the deflection occurs, may depend respectively upon the magnitude and sign of the actuation voltage Va. A negative actuation voltage may cause cantilever 900 to deflect in a first direction and a positive actuation voltage may cause cantilever 900 to deflect in a second direction that is opposite to the first direction. In some embodiments, the voltage source may be configured to apply one or more discrete actuation voltages, each of which may drive cantilever 900 into a distinct deflection state.

### Active Curving Cantilevers for Photonic Applications

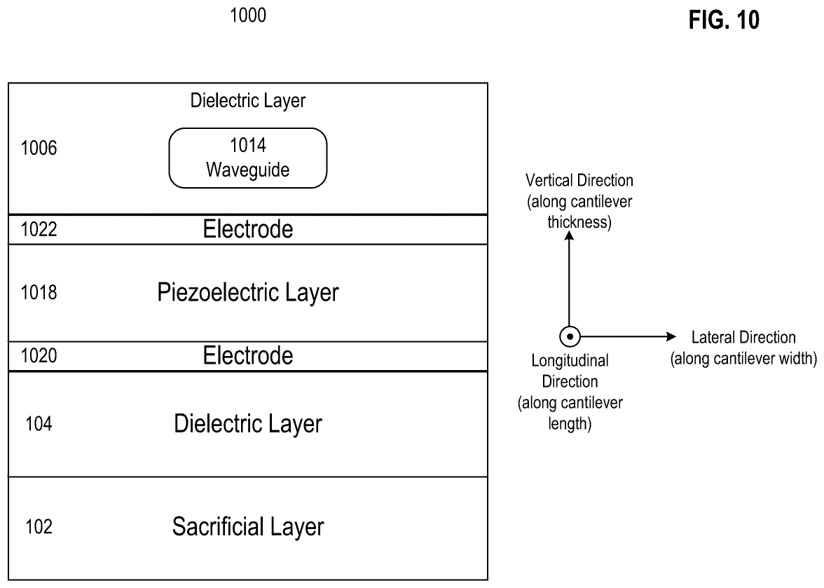

Active control of cantilever curvature may be particularly useful for cantilevers that are components of photonic systems. As shown in FIG. 10, a cantilever 1000 can include both a waveguide 1014 (patterned within a top dielectric layer 1006) and a piezoelectric layer 1018. Varying the actuation voltage applied across piezoelectric layer 1018 may cause cantilever 1000—and, as a result, waveguide 1014—to sweep through one or more deflected states. In each deflected state, waveguide 1014 may optically couple to a different optoelectronic component. Cantilever 1000 may therefore function as an optical switch that enables optical signals to be selectively coupled into or selectively received from multiple different optoelectronic devices.

Driving an active curving cantilever such as cantilever 1000 using an alternating current (AC) actuation voltage may significantly amplify the beam output range of the cantilever waveguide.

The subsequent sections provide various (non-limiting) example applications of the cantilevers described herein.

### Example 1: Origami

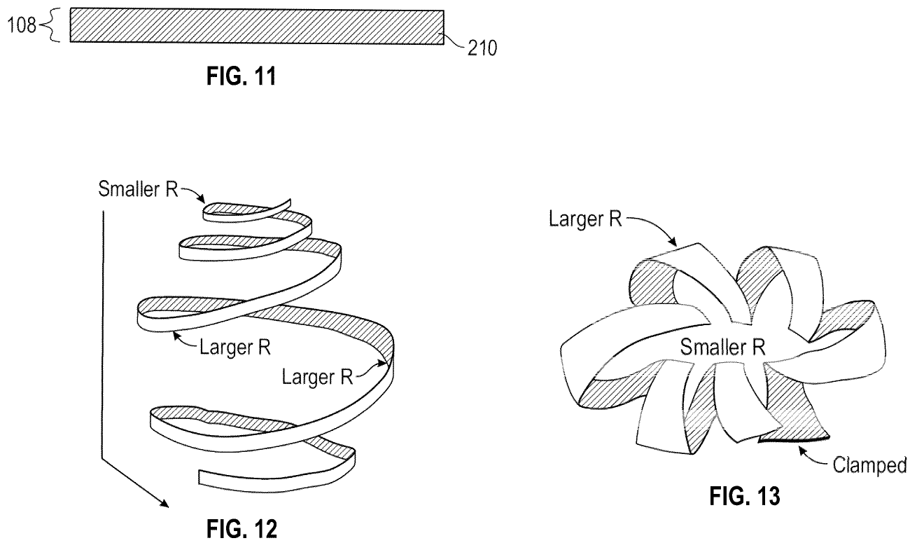

A cantilever can be deterministically configured to assume a helical structure when released by patterning its topmost dielectric layer with crossbars that are oriented diagonally with respect to the cantilever length, as illustrated in FIG. 11. More intricate three-dimensional shapes such as those depicted in FIGS. 11, 12, and 13 may be obtained by patterning the crossbars such that the radius of curvature R of the helix varies along the length of the cantilever when the cantilever is released. For example, a ball may be created by patterning the crossbars such that, when the cantilever is released, the radius of curvature R of the cantilever is starts out relatively small near one end, increases along the cantilever length, and then decreases again toward the other end (FIG. 12). A toroid may be created by modulating the radius of curvature R at the same spatial period as the helical twist such that a larger radius R appears at the same point in the twist, causing the helix to turn and, eventually, close on itself (FIG. 13). Additional shapes can be obtained via similar modulation of the stress magnitude and directionality. Complex structures may be self-assembled by combining multiple cantilevers configured to obtain more basic shapes.

### Example 2: Micron-Scale Gripping Actuators

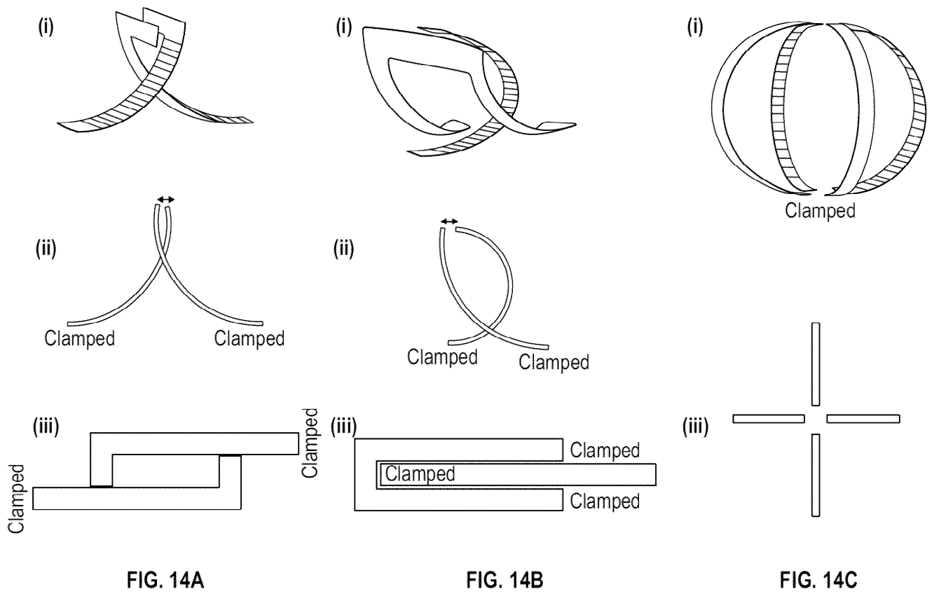

Micron-scale gripping actuators can be formed by counter-posing two or more cantilevers, as shown in FIGS. 14A-14C. The topmost dielectric layers on the cantilevers in a gripping actuator may be patterned with crossbars such that, when the cantilevers are released, the cantilevers curl toward one another. The deflection of the cantilevers in a gripping actuator may be piezoelectrically controlled so that the gripping actuator can be selectively opened and closed. These actuators may be implemented in micro-robotic systems.

### Example 3: Sideways-Twisting Cantilever with Waveguide

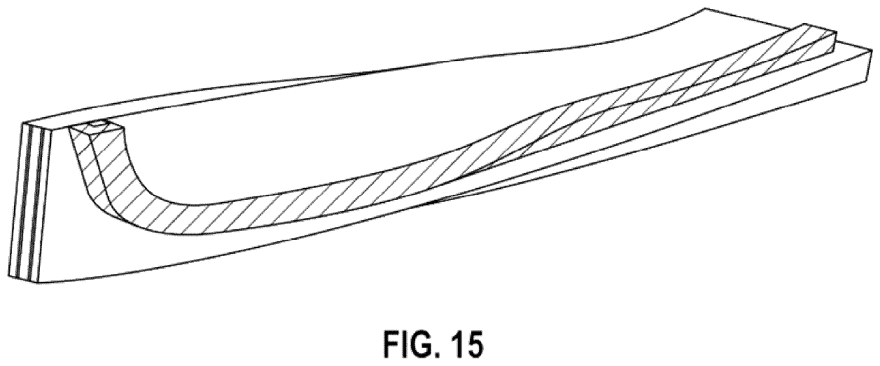

The downward stress of the waveguide channel in a piezoelectrically actuated cantilever with a waveguide may generate a stress gradient that causes twisting which allows the edge opposite the waveguide to turn up, as illustrated in FIG. 15. In FIG. 15, the waveguide (shown in hashing) is offset from the center of cantilever, creating a stress gradient that causes the side of the cantilever opposite the waveguide to twist upward with respect to the side of the cantilever with the waveguide

### Example 4: “Candy-Cane” Photonic Coupler

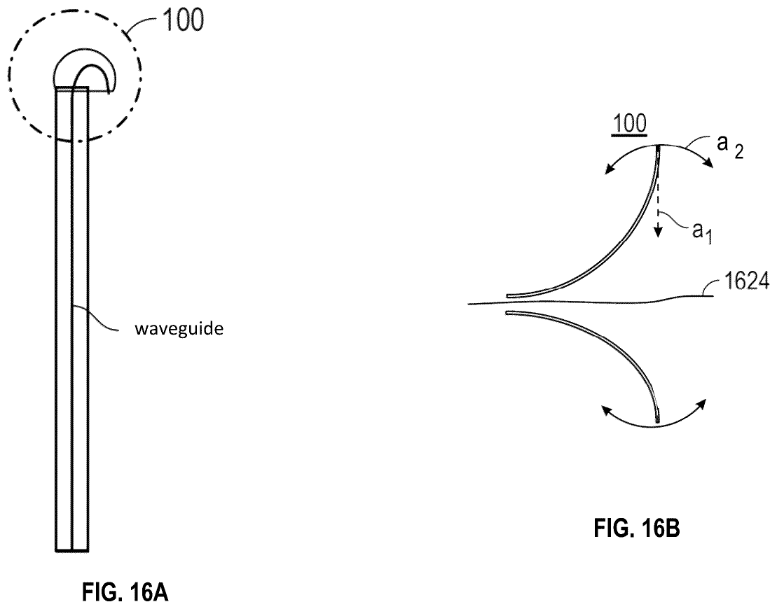

A piezoelectrically actuated cantilever with a waveguide can be used to form a “candy-cane”-shaped photonic coupler, as illustrated in FIGS. 16A-B. The cantilever may be used to direct the waveguide toward a reflective substrate (1624 in FIG. 16B), as indicated by arrow a₁. An optical signal directed to the reflective substrate by the waveguide may reflect perpendicularly to the reflective substrate. This embodiment may thus be used to correct for optical aberrations by shifting of the vertical location of the waveguide output by actuating the cantilever, as indicated by arrow a₂.

### Example 5: “Stair-Step” Photonic Coupler

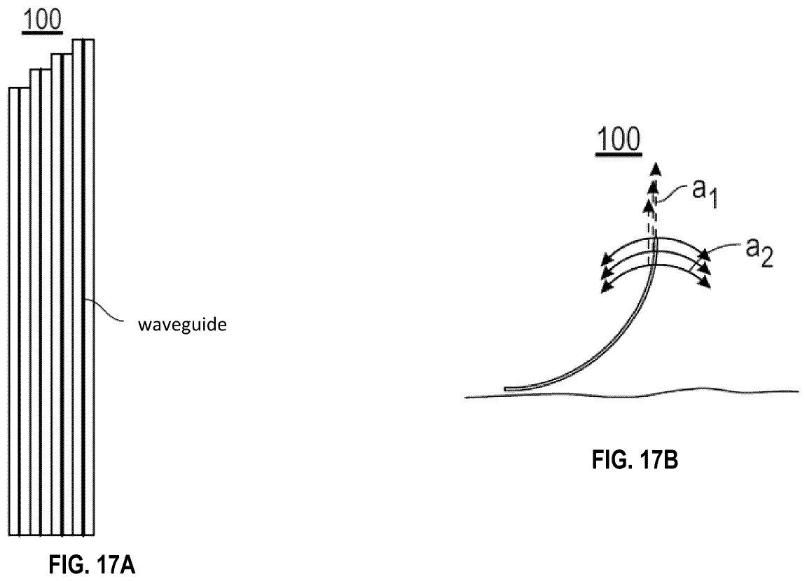

A piezoelectrically-actuated cantilever may be patterned with multiple waveguides of varying lengths to form a “stair-step” photonic coupler, as shown in FIGS. 17A-17B. The cantilever may be etched so that, from a top-down perspective, the emitting end of the cantilever has “stair-step” shape. When the cantilever is actuated (as indicated by arrows a₂), each waveguide may emit at a different vertical location relative to the cantilever's substrate (indicated by arrows a₁). Changing the waveguide through which an optical signal is transmitted may change the vertical output location of the optical signal which may, in turn, adjust the focal plane of the optical signal. This may enable the optical beam to be focused at another location.

### Example 6: Angle-Boosted Cantilever

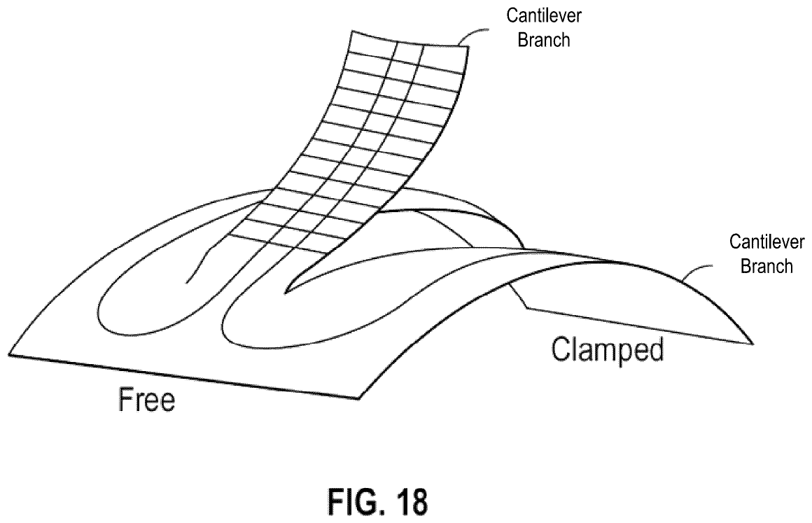

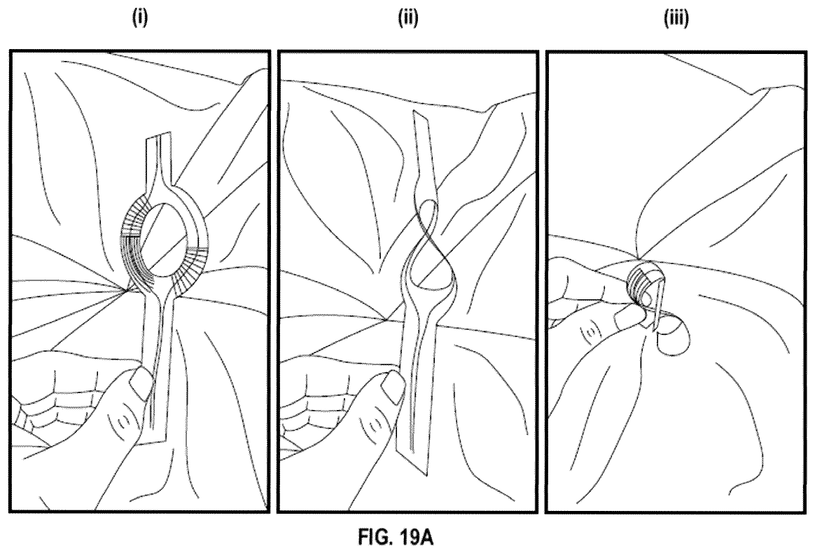

A cantilever patterned with crossbars oriented orthogonally to its length may deflect vertically along its length when released. The vertical deflection of such a cantilever may be enhanced over a shorter longitudinal distance by fabricating cantilever such that it branches from a downward-bending, bridge-shaped cantilever, as shown in FIG. 18. The bridge-shaped cantilever branch may comprise one clamped end that is anchored to a substrate as well as one free end. The bridge-shaped cantilever branch may comprise a top oxide and nitride coating that forces the branch to arch downward (e.g., toward a substrate). The free end of the bridge-shaped cantilever branch may be oriented at a non-zero angle relative to the substrate. The cantilever branch that deflects vertically away from the substrate may initially be oriented at the same non-zero angle relative to the substrate as the bridge-shaped branch, i.e., may initially be vertically deflected relative to the substrate by a non-zero amount. This vertically deflecting cantilever branch may achieve greater vertical deflection over a shorter distance.

### Example 7: Piezoelectric Control of Cantilever Twist and Torsion

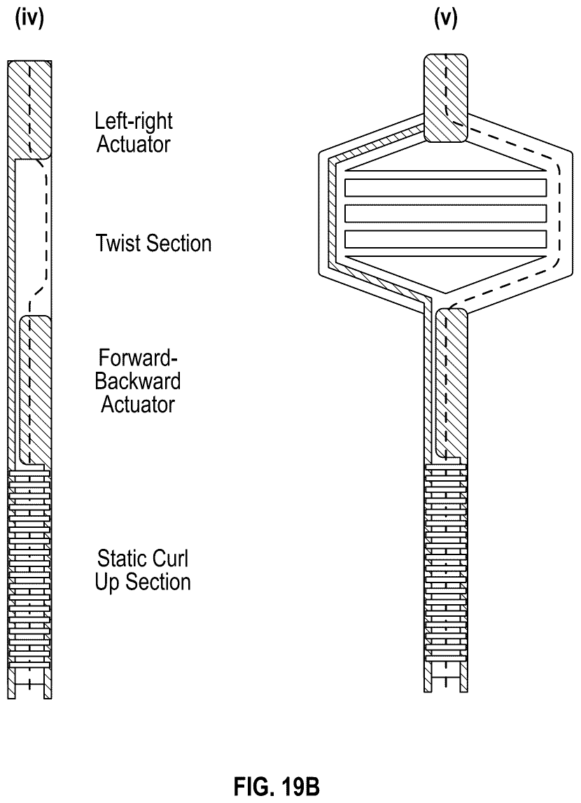

FIG. 19A-B depicts examples of helically-twisted, piezoelectrically-actuated cantilever structures. In these examples, motion along the lateral direction is achieved by twisting the cantilever body by 90° using a first piezoelectric actuator and driving lateral motion using a second piezoelectric actuator. This may be achieved by creating a double-helical section wherein the stress of the crossbars is engineered such that the two branches first bend in away from one another, then bend toward one another. As shown, this may require that one branch has crossbars in the lateral direction while the other has crossbars in the longitudinal direction.

The helically-twisted cantilever structures can be used to form a Z-actuator. Such an actuator may comprise four distinct sections: an initial upward bending section with orthogonally-oriented crossbars, a stress-neutral actuator section that moves the tip longitudinally, a helical or twist section which rotates the cantilever by 90 degrees about its longitudinal axis, and a second stress neutral section that moves the tip laterally. Such structures can also be combined with the angle-boosting structures described in Example 6.

Diagrams (i)-(iii) in FIG. 19A depict demonstrations of shapes for helically-twisted, piezoelectrically-actuated cantilever structures.

Diagrams (iv) and (v) in FIG. 19B depict different components of twisting piezoelectrically-actuated cantilever structures. In diagram (iv), a first piezoelectric component runs up the left side of the cantilever and actuates a central section of the cantilever. A twist section of the cantilever twists due at least in part to the waveguide (shown by a dashed line) being offset from the center of the cantilever in this section. Finally, a second piezoelectric component runs up the right side of the cantilever and actuates a distal section of the cantilever (at the top of the figure). In diagram (v), a similar arrangement is provided, except that the waveguide is routed dramatically off-center to the right from the center-line of the cantilever, and the second piezoelectric component is routed symmetrically dramatically off-center to the left from the center-line of the cantilever; this arrangement may provide increased twisting.

### Example 8: Ball-Lens Terminated Cantilever

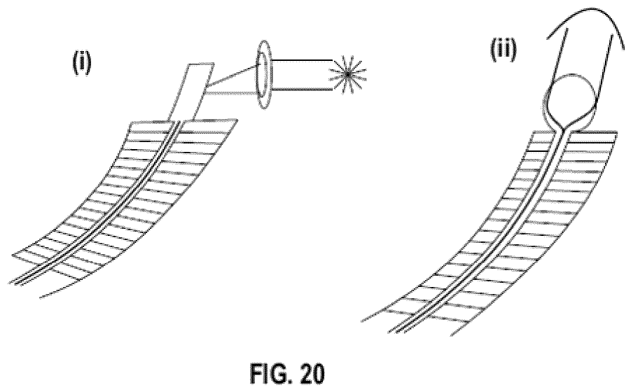

FIGS. 20A-B shows a ball-lens-terminated cantilever. This embodiment may provide direct collimation of output light from waveguides on the cantilever without requiring a bulk objective or lens above the chip to collimate and direct the output beam. Diagram (i) shows a fabrication process in which material for forming a ball lens is melted onto a tip of the cantilever. Diagram (ii) shows the cantilever with ball lens tip after fabrication.

### Example 9: Periodic Optical Switches

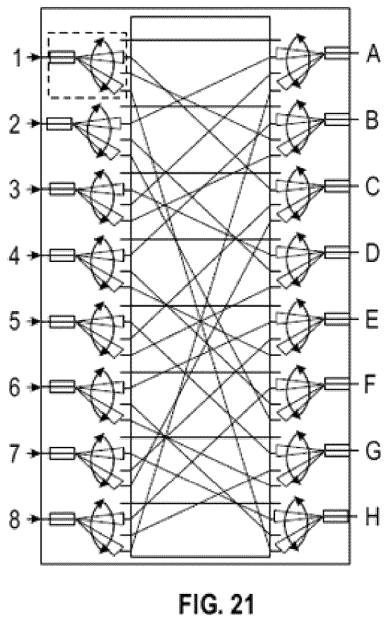

A piezoelectrically-actuated cantilever with a waveguide may be used as 1×N optical switch, as shown in FIG. 21. The cantilever may be adjusted between N distinct deflected states by applying varying actuation voltages across the piezoelectric layer. In each deflected state, the waveguide may optically couple to a different output.

### Example 10: Photonic Cantilever with Low Output Divergence

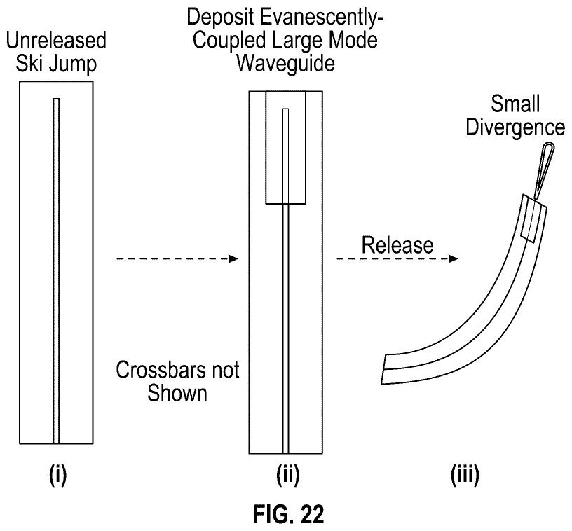

FIG. 22 shows techniques for creating low output divergence photonic cantilevers. Diagram (i) shows an unreleased cantilever. Diagram (ii) shows depositing an evanescently-coupled large mode waveguide. Diagram (iii) shows release of the cantilever and small divergence from the waveguide. As shown, an evanescently coupled large mode waveguide may be deposited at an output end of a waveguide that is patterned on a cantilever. Coupling between the cantilever waveguide and the large mode waveguide may result in low divergence output from the cantilever waveguide.

### Example 11: Beam Steering and Routing of Laser Light in a Photonic Integrated Circuit

In a piezoelectrically-actuated cantilever with a waveguide, crossbars can be patterned at a number of crossbar widths and duty cycles to achieve the enhanced curling. In particular, keeping the crossbars relatively thin (e.g., 1 μm) but increasing the crossbar period from (e.g., from 2 μm to 8 μm) may enhance upward curling for the same length and width of cantilever. This level of curling enhancement may allow at least two waveguides in an array on a single cantilever to in parallel or in sequence to direct light out-of-plane on and off a photonic integrated circuit (PIC) from any location on the chip where such a cantilever is fabricated. Multiple wavelengths, polarizations, laser sources, or photon sources (e.g., from qubit color centers) can be routed simultaneously off chip. The vertical waveguide input/output may have greater independence from wavelength/frequency and polarization of light compared to gratings for on/off PIC coupling. Further optimization of the crossbar geometry to balance re-direction of strain from the width to along the length (waveguide direction) of the cantilever with minimized top oxide strips that can also cause downward curling of the cantilever could further decrease the length of cantilever needed to achieve verticality, thereby improving stability of the device and increasing resonant drive frequencies. Such devices may have applications in multi-color imaging/projection, and the initialization/readout of prototypical qubits (color centers) in diamond.

### Example 12: Resonant Driving of Near-Vertical Cantilevers

A piezoelectrically-actuated cantilever with a waveguide that is nearly-vertically deflected can be driven at resonance to enable significant enhancement of the individual modes accessible for beam steering and control. Driving at one of the higher order modes may maximize the lateral displacement of the beam output with minimized deflection in the vertical direction. This may optimize the cantilever's use as a beam steering device. The cantilevers can be driven on and off resonance up to megahertz frequencies for many hours without degradation.

### Example 13: High-Speed Optical Pulsing for Qubit Control

A piezoelectrically actuated cantilever with a waveguide can be driven with an AC signal once curled to quickly and directly route light output from the waveguide onto diamond chiplet containing via color centers or to route the light via a lens system to the diamond chiplet to quickly pulse light on and off for initialization and readout of the color center. With multiple parallel waveguides on the cantilever, color centers in multiple diamond waveguides can be controlled for readout along the length of the waveguide.

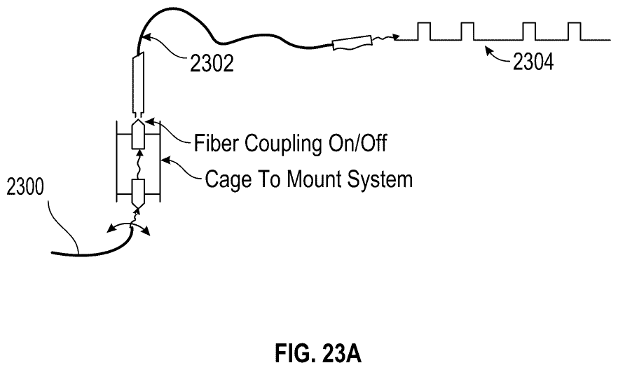

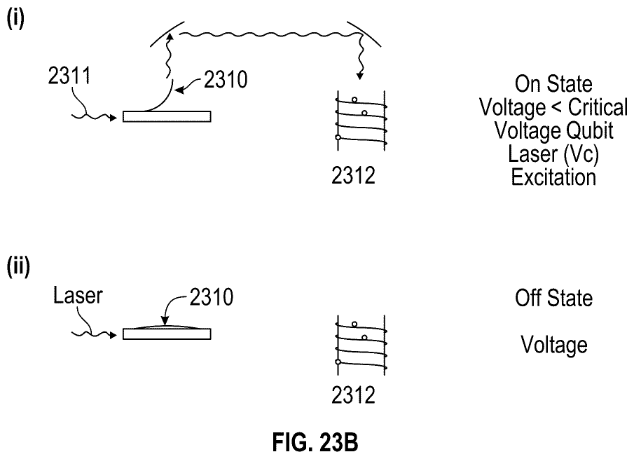

FIG. 23A shows a photonic integrated chip with a cantilever with waveguide 2300, curled 90 degrees upward, directing light vertically out of the chip. Above the PIC chip is a lens or objective to collimate the output beam of light. The light is then routed to a second lens or objective that couples the light to an optical fiber 2302. The optical fiber is routed to a desired location with a collimating lens at the appropriate end. This light can be sent to any desired location. If the cantilever is driven at high speed back and forth, the light out of the cantilever will at one point in time be coupled into the optical fiber to the output on the other end. At other points in time, no light will be coupled and, as a result, there will be light at the other end of the optical fiber. The cantilever can be driven via piezo-actuation at a desired frequency to create pulses of light 2304 at different lengths and periods at the far end of the optical fiber. Driving of the cantilever back and forth can thus be used to modulate the coupling to the optical fiber to form the pulse train 2304. This may be useful for generating short pulses of light, similar to acousto-optic modulators, the latter of which are typically commercial bulky devices. The pulses of light could be used to optically initialize and read out the quantum states of solid-state qubits such as color center atomic defects in diamonds. The pulses may also be used in information transfer of 0s and 1 corresponding to no light (0) and a pulse of light (1).

Referring to FIG. 23B, some cantilever devices may exhibit a behavior wherein, above a certain piezo-voltage threshold, the cantilever 2310 snaps down into the plane of the photonic integrated circuit (as shown in diagram (i)). When the voltage is decreased below this threshold, the cantilever 2310 returns to its original position (as shown in diagram (ii)). This may allow for a binary switch of on and off for the cantilever. When the cantilever is pointing vertically upward as in diagram (i), the light from a laser source 2311 can be directed via lenses and mirrors onto a diamond chiplet 2312 that contains color center atomic defect qubits. The light can be used to initialize and read out the quantum state of the qubits. By using this binary switch behavior, pulses of light can be sent at desired times in a quantum control sequence to control the qubits on the diamond chiplet. The snapping behavior could also be used just to set up a digital pulse train of 0s and 1s for information transfer via the two binary states of the cantilever being curled upward and when the cantilever is snapped into the plane of the chip. Diagram (i) shown an ON state of a PIC, where voltage is below a threshold voltage amount and chiplet 2321 is excited, and diagram (ii) shows an OFF state of the PIC, where voltage is above the threshold voltage amount and the chiplet 2321 is not excited.

### Example 14: Top-Down and Edge Excitation of and Collection from Qubit Color Centers

A piezoelectrically-actuated cantilever with a waveguide may be used for more efficient control of prototypical qubit color centers relative to photonic integrated circuit (PIC) edge excitation and collection or top-down confocal excitation and collection. The boundary of the waveguide output on the curled cantilever can be repeatedly defined to high fabrication fidelity and precision relative to cleaving of PICs for edge coupling. This may allow for outputs off-PIC anywhere on the PIC without requiring long waveguides to route all photons to the edge of the chip.

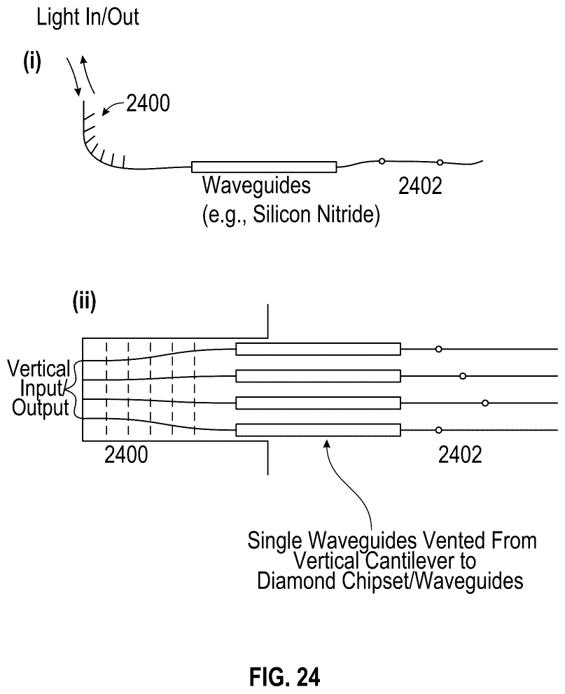

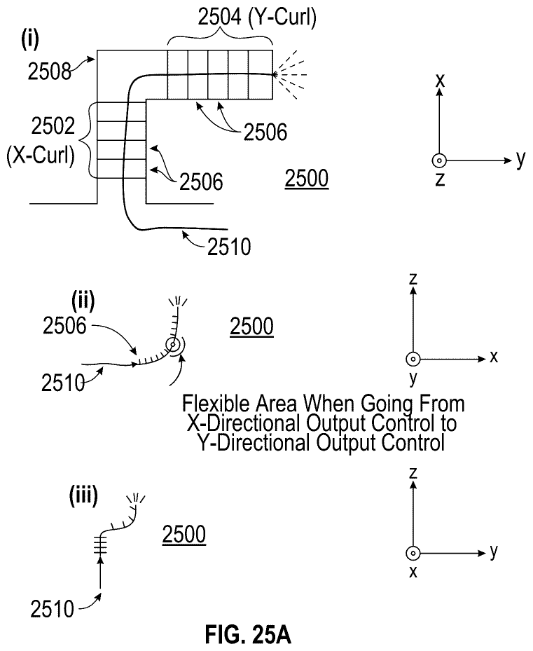

FIG. 24 shows an example whereby laser light is input into one or more waveguides at the end of the cantilever 2400. The light is routed down the waveguides onto the plane of the chip. The waveguides are then coupled to waveguides on a diamond chiplet 2402 that contain the prototypical qubit color centers. The light interacts with the color center. The color center will emit light in response that can go back through the waveguides, up the cantilever and be read at the output of the cantilever. Therefore, the cantilever can be used as a more efficient method to initialize and readout the quantum state of the color center qubit compared to the other methods listed in Example 15. The example embodiment in FIG. 24 has an array of four waveguides on the cantilever, sending control signals to qubits in four different diamond arrays. This is to demonstrate the scalability of the device to control multiple color center qubits via different channels on the same cantilever.

### Example 15: Two-Dimensional Control of Cantilever Segments

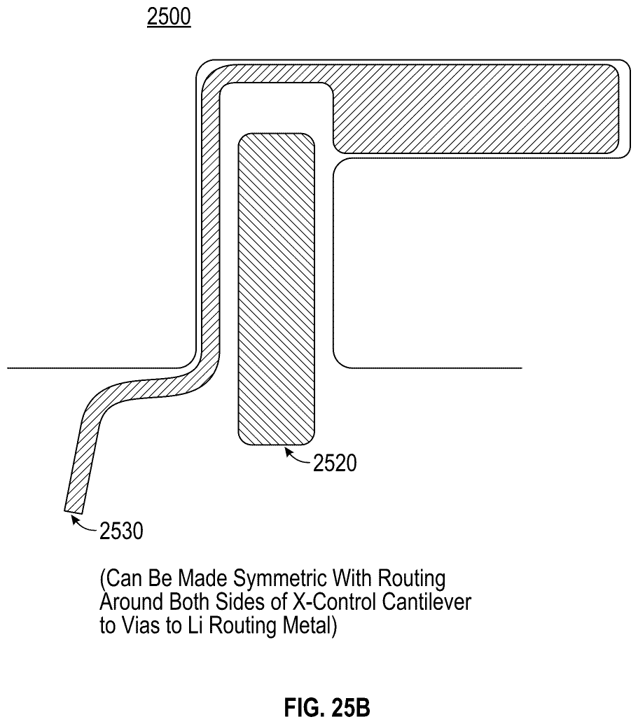

FIG. 25A-25B depict cantilevers 2500 with two independent directionally controlled segments 2502 (x-curl) and 2504 (y-curl). The cantilever segments may be orthogonal to each other. Each segment may comprise crossbars 2506 to ensure rigidity. A non-crossbar “flexture” region 2508 may connect the two segments. If the segments are patterned with waveguides 2510, and each segment curls at 45°, a total angle up and output of waveguides from plane of chip may be at least 60°. Such a cantilever may be implemented on a photonic integrated circuit on angle mounted stage at approximately 24° relative to flat ground or angle objective at 24° relative to a standard vertical location above the photonic integrated chip. This design can allow independent control in two perpendicular directions for beam steering. Diagrams (i)-(iii) in FIG. 25A show three different cartesian views of cantilever 2500. FIG. 25B shows piezo-stack control sections of cantilever 2500. As shown, electrode piezo-stack 2520 may control segment 2502, and electrode piezo-stack 2530 may control segment 2504. In some embodiments, electrode piezo-stack 2530 may be made symmetric with routing around both sides of electrode piezo-stack 2520.

The foregoing description, for the purpose of explanation, has been described with reference to specific embodiments and/or examples. However, the illustrative discussions above are not intended to be exhaustive or to limit the invention to the precise forms disclosed. Many modifications and variations are possible in view of the above teachings. The embodiments were chosen and described in order to best explain the principles of the techniques and their practical applications. Others skilled in the art are thereby enabled to best utilize the techniques and various embodiments with various modifications as are suited to the particular use contemplated.

Although the disclosure and examples have been fully described with reference to the accompanying figures, it is to be noted that various changes and modifications will become apparent to those skilled in the art. Such changes and modifications are to be understood as being included within the scope of the disclosure and examples as defined by the claims. Finally, the entire disclosure of the patents and publications referred to in this application are hereby incorporated herein by reference.

1. A cantilever comprising:
a first dielectric layer, wherein the first dielectric layer has a first intrinsic stress;
a second dielectric layer overlying the first dielectric layer, wherein the second dielectric layer has a second intrinsic stress that is different than the first intrinsic stress,
wherein the cantilever is curved along a longitudinal dimension of the cantilever due to a difference between the first and second intrinsic stresses, and
wherein the second dielectric layer comprises a plurality of crossbars oriented at an angle relative to a length of the cantilever to control curvature in a lateral dimension of the cantilever.

2. The cantilever of claim 1, wherein a patterning of the plurality of crossbars is periodic.

3. The cantilever of claim 2, wherein a period of the patterning of the plurality of crossbars is greater than or equal to 0.5 microns.

4. The cantilever of claim 1, wherein each crossbar of the plurality of crossbars has a length greater than or equal to 0.25 microns and less than or equal to 5 microns.

5. The cantilever of claim 1, wherein a length of each crossbar of the plurality of crossbars is greater than a period of the patterning of the plurality of crossbars.

6. The cantilever of claim 1, wherein a ratio of the length of each crossbar of the plurality of crossbars to the period of the patterning of the plurality of crossbars is at least 0.5.

7. The cantilever of claim 5, wherein a ratio of the length of each crossbar of the plurality of crossbars to the period of the patterning of the plurality of crossbars changes along the longitudinal dimension of the cantilever.

8. The cantilever of claim 1, wherein each crossbar of the plurality of crossbars protrudes from a surface of the second dielectric layer.

9. The cantilever of claim 8, wherein a height of each crossbar of the plurality of crossbars relative to the surface of the second dielectric layer is greater than 0 microns and less than or equal to 2 microns.

10. The cantilever of claim 1, wherein the angle at which the plurality of crossbars is patterned is approximately 90°.

11. The cantilever of claim 1, wherein the angle at which the plurality of crossbars is patterned is less than 90°.

12. The cantilever of claim 1, wherein the cantilever is fabricated with a removable sacrificial layer that binds the cantilever to a substrate, wherein, when the sacrificial layer is removed, the cantilever deflects along the longitudinal dimension of the cantilever relative to the substrate.

13. The cantilever of claim 12, wherein the cantilever deflects in a direction away from the substrate.

14. The cantilever of claim 12, wherein the cantilever deflects in a direction toward the substrate.

15. The cantilever of claim 12, wherein the deflection of the cantilever relative to the substrate increases from the first end along the longitudinal dimension of the cantilever.

16. The cantilever of claim 12, wherein a maximum deflection of the cantilever along the longitudinal dimension of the cantilever is at least 1 mm.

17. The cantilever of claim 1, wherein a chemical composition of the first dielectric layer is the same as a chemical composition of the second dielectric layer.

18. The cantilever of claim 1, wherein the second dielectric layer comprises an oxide.

19. The cantilever of claim 1, comprising one or more waveguides.

20. The cantilever of claim 19, wherein the one or more waveguides are patterned in the second dielectric layer.

21. The cantilever of claim 19, wherein the one or more waveguides are patterned along the longitudinal dimension of the cantilever.

22. The cantilever of claim 19, wherein the cantilever is a component of a photonic integrated circuit.

23. The cantilever of claim 1, comprising a piezoelectric layer disposed between the first dielectric layer and the second dielectric layer, wherein the piezoelectric layer has a third intrinsic stress that is greater than the first intrinsic stress of the first dielectric layer.

24. The cantilever of claim 23, wherein, when a voltage is applied across the piezoelectric layer, cantilever deflects along its length relative to the substrate.

25. The cantilever of claim 24, wherein the direction of the deflection of the cantilever relative to the substrate depends on the sign of the voltage applied to the piezoelectric layer.

26. The cantilever of claim 24, wherein an amount by which the cantilever deflects relative to the substrate depends on the magnitude of the voltage applied to the piezoelectric layer.

27. The cantilever of claim 1, wherein the cantilever is a component of a clamping device.

28. The cantilever of claim 1, wherein the cantilever curls along its length to form a helix.

29. The cantilever of claim 1, wherein:
the longitudinal dimension of the cantilever in a first portion of the cantilever is oriented in a first direction, and
the longitudinal dimension of the cantilever in a second portion of the cantilever is oriented in a second direction.

30. The cantilever of claim 29, wherein the second direction is orthogonal to the first direction.

31. The cantilever of claim 1, comprising a ball lens disposed at one end of the cantilever.

32. The cantilever of claim 1, comprising one or more layers disposed between the first dielectric layer and the second dielectric layer.

33. A photonic system comprising:
a photonic integrated circuit (PIC) chip comprising a cantilever, the cantilever comprising:
a first dielectric layer, wherein the first dielectric layer has a first intrinsic stress;
a second dielectric layer overlying the first dielectric layer, wherein the second dielectric layer has a second intrinsic stress that is different than the first intrinsic stress; and
a waveguide patterned in the second dielectric layer;
wherein the cantilever is curved along a longitudinal dimension of the cantilever due to a difference between the first and second intrinsic stresses, and
wherein the second dielectric layer comprises a plurality of crossbars oriented at an angle relative to the longitudinal dimension of the cantilever to control curvature in a lateral dimension of the cantilever.

34. The photonic device of claim 33, wherein:
the cantilever is fabricated with a removable sacrificial layer that binds the cantilever to a substrate of the PIC chip,
when the sacrificial layer is removed, the cantilever deflects in a direction along the longitudinal dimension of the cantilever relative to the substrate.

35. The photonic device of claim 33, wherein the waveguide is patterned along the longitudinal dimension of the cantilever.

36. The photonic device of claim 34, comprising an optoelectronic component, wherein the optoelectronic component is not a component of the PIC chip, wherein the waveguide is configured to optically couple to the optoelectronic component when the cantilever deflects relative to the substrate.

37. The photonic device of claim 33, comprising a piezoelectric layer disposed between the first dielectric layer and the second dielectric layer, wherein the piezoelectric layer has a third intrinsic stress that is greater than the first intrinsic stress of the first dielectric layer.

38. The photonic device of claim 37, wherein the cantilever deflects along the longitudinal dimension of the cantilever when a voltage is applied across the piezoelectric layer.

39. The photonic device of claim 38, wherein the direction of the deflection of the cantilever relative the substrate depends on the sign of the voltage applied to the piezoelectric layer.

40. The photonic device of claim 38, wherein an amount by which the cantilever deflects relative to the substrate depends on the magnitude of the voltage applied to the piezoelectric layer.

41. A system comprising:
a substrate;
a first cantilever anchored to the substrate at one end, wherein the first cantilever forms an arch along its length over the substrate; and
a second cantilever anchored to the first cantilever at one end and comprising:
a first dielectric layer, wherein the first dielectric layer has a first intrinsic stress;
a second dielectric layer overlying the first dielectric layer, wherein the second dielectric layer has a second intrinsic stress that is different than the first intrinsic stress,
wherein the second cantilever is curved along a longitudinal dimension of the second cantilever due to a difference between the first and second intrinsic stresses, and
wherein the second dielectric layer comprises a plurality of crossbars oriented at an angle relative to the longitudinal dimension of the second cantilever to control curvature in a lateral dimension of the cantilever.

42. A cantilever comprising:
a first dielectric layer, wherein the first dielectric layer has a first intrinsic stress;
a second dielectric layer overlying the first dielectric layer, second dielectric layer has a second intrinsic stress that is different than the first intrinsic stress, wherein a difference between the first and second intrinsic stresses causes the cantilever to curve.

43. A cantilever comprising:
a first dielectric layer, wherein the first dielectric layer has a first intrinsic stress;
a second dielectric layer overlying the first dielectric layer, wherein the second dielectric layer has a second intrinsic stress that is different than the first intrinsic stress,
a first piezoelectric layer disposed between the first dielectric layer and the second dielectric layer in a first longitudinal half of the cantilever; and
a second piezoelectric layer disposed between the first dielectric layer and the second dielectric layer in a second longitudinal half of the cantilever.

44. A system comprising:
the cantilever of claim 43; and
one or more voltage sources configured to apply a first voltage to the first piezoelectric layer and a second voltage to the second piezoelectric layer.

45. A cantilever comprising:
a first dielectric layer, wherein the first dielectric layer has a first intrinsic stress;
a second dielectric layer overlying the first dielectric layer, wherein the second dielectric layer has a second intrinsic stress that is different than the first intrinsic stress,
a first piezoelectric layer disposed between the first dielectric layer and the second dielectric layer in a first lateral portion of the cantilever; and
a second piezoelectric layer disposed between the first dielectric layer and the second dielectric layer in a second lateral portion of the cantilever.

46. A system comprising:
the cantilever of claim 45; and
one or more voltage sources configured to apply a first voltage to the first piezoelectric layer and a second voltage to the second piezoelectric layer.
